(19) United States
(12) Patent Application Publication
(10) Pub. No.: US 2026/0165171 A1
(43) Pub. Date: Jun. 11, 2026

(54) PACKAGE SUBSTRATE INCLUDING EMBEDDED DIE AND METHODS OF FORMING THE SAME

(71) Applicant: Taiwan Semiconductor Manufacturing Company Limited, Hsinchu (TW)

(72) Inventors: Chuei-Tang Wang, Taichung City (TW); Yen-Ming Chen, Hsinchu (TW); Yu-Ming Hsiao, Hsinchu (TW); Shu An Shang, Kaohsiung City (TW); Kam Heng Lee, Hsinchu City (TW)

(21) Appl. No.: 18/976,927

(22) Filed: Dec. 11, 2024

(51) Int. Cl. H01L 23/498; H01L 21/56; H01L 23/00; H01L 23/31; H01L 23/48; H01L 25/065; H01L 25/10

(52) U.S. Cl. CPC H10W 70/685; H10W 20/20; H10W 70/65; H10W 74/016; H10W 74/117; H10W 90/00; H10W 70/60; H10W 74/10; H10W 80/312; H10W 80/327; H10W 90/297; H10W 90/724; H10W 90/792; H10W 90/794

(57) ABSTRACT

A package substrate includes a core, a dielectric filling layer, and a die in the dielectric filling layer, including a device region on a first side of the die, and a through silicon via (TSV) extending from the first side of the die, through the device region, and to a second side of the die opposite the first side of the die. A method of making a package substrate includes providing a core, mounting a die at least one of on the core or in the core, wherein the die includes a device region on a first side of the die, and a TSV extending from the first side of the die, through the device region, and to a second side of the die opposite the first side of the die, and forming a dielectric filling layer around the die.

### BACKGROUND

A package structure (e.g., advanced packaging) may include a package substrate having a core. The core of the package substrate may include plated through holes (PTH). The plated through holes may connect two ends of the core (e.g., top and bottom) as a power supply path.

A die (e.g., semiconductor die) including one or more components (e.g., active or passive components such as capacitors, inductors, integrated voltage regulators (IVRs), etc.) may be embedded in the package substrate. In instances in which the package substrate is a cored substrate, the die may be embedded inside the core.

Embedding a die in the core of the substrate may help to improve power integrity (PI) performance of the package structure. A thickness of the die may need to be close to the thickness of the core in which the die is embedded. For example, a die embedded in the core may have a thickness in a range of 600 μm to 700 μm (e.g., about 650 μm). Thus, it may be desirable to provide a core with a thickness in the same range in order to accommodate the die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package substrate according to one or more embodiments.

FIG. 1B is a detailed vertical cross-sectional view of a portion of the package substrate including the die according to one or more embodiments.

FIG. 1C is a detailed top-down view (e.g., plan view) of a portion of the package substrate including the die according to one or more embodiments.

FIG. 2A is a vertical cross-sectional view of an intermediate structure including the core on a first carrier substrate (e.g., carrier wafer) according to one or more embodiments.

FIG. 2B is a vertical cross-sectional view of an intermediate structure including the core opening in the core according to one or more embodiments.

FIG. 2C is a vertical cross-sectional view of an intermediate structure including the die in the core opening according to one or more embodiments.

FIG. 2D is a vertical cross-sectional view of an intermediate structure including a portion of the dielectric filling layer on the die according to one or more embodiments.

FIG. 2E is a vertical cross-sectional view of an intermediate structure including openings (e.g., via holes) in the dielectric filling layer upper portion according to one or more embodiments.

FIG. 2F is a vertical cross-sectional view of an intermediate structure including metal vias in the dielectric filling layer upper portion according to one or more embodiments.

FIG. 2G is a vertical cross-sectional view of an intermediate structure including the dielectric filling layer lower portion according to one or more embodiments.

FIG. 2H is a vertical cross-sectional view of an intermediate structure including metal vias in the dielectric filling layer lower portion and a metal layer on the dielectric filling layer lower portion according to one or more embodiments.

FIG. 2I is a vertical cross-sectional view of an intermediate structure including the lower build-up portion according to one or more embodiments.

FIG. 2J is a vertical cross-sectional view of an intermediate structure including the upper build-up portion according to one or more embodiments.

FIG. 3 is a flow chart illustrating a method of making a package substrate according to one or more embodiments.

FIG. 4A is a vertical cross-sectional view of the package substrate having a first alternative configuration according to one or more embodiments.

FIG. 4B is a vertical cross-sectional view of the die stack in the package substrate having the first alternative configuration according to one or more embodiments.

FIG. 4C is a vertical cross-sectional view of the die stack having an alternative configuration according to one or more embodiments.

FIG. 5 is a vertical cross-sectional view of a package substrate having a second alternative configuration according to one or more embodiments.

FIG. 6A is a vertical cross-sectional view of an intermediate structure including the lower core on the first carrier substrate (e.g., carrier wafer) according to one or more embodiments.

FIG. 6B is a vertical cross-sectional view of an intermediate structure including the upper core stacked on the lower core according to one or more embodiments.

FIG. 6C is a vertical cross-sectional view of an intermediate structure including the die in the core opening according to one or more embodiments.

FIG. 6D is a vertical cross-sectional view of an intermediate structure including the dielectric filling layer on the die according to one or more embodiments.

FIG. 6E is a vertical cross-sectional view of an intermediate structure including openings (e.g., via holes) in the dielectric filling layer upper portion according to one or more embodiments.

FIG. 6F is a vertical cross-sectional view of an intermediate structure including the metal vias in the dielectric filling layer upper portion according to one or more embodiments.

FIG. 6G is a vertical cross-sectional view of an intermediate structure including the upper build-up portion according to one or more embodiments.

FIG. 6H is a vertical cross-sectional view of an intermediate structure including the lower build-up portion according to one or more embodiments.

FIG. 7 is a flow chart illustrating a method of making a package substrate according to one or more embodiments.

FIG. 8 is a vertical cross-sectional view of a package substrate having a third alternative configuration according to one or more embodiments.

FIG. 9 is a vertical cross-sectional view of a package substrate having a fourth alternative configuration according to one or more embodiments.

FIG. 10A is a vertical cross-sectional view of a package substrate having a fifth alternative configuration according to one or more embodiments.

FIG. 10B is a vertical cross-sectional view of a different version of the package substrate having a fifth alternative configuration according to one or more embodiments.

FIG. 11A is a vertical cross-sectional view of an intermediate structure including the core with the upper prepreg layer according to one or more embodiments.

FIG. 11B is a vertical cross-sectional view of an intermediate structure including the metal vias and the upper metal layer on the upper prepreg layer according to one or more embodiments.

FIG. 11C is a vertical cross-sectional view of an intermediate structure including the lower prepreg layer according to one or more embodiments.

FIG. 11D is a vertical cross-sectional view of an intermediate structure including the upper build-up portion according to one or more embodiments.

FIG. 11E is a vertical cross-sectional view of an intermediate structure including the die stack (first die stack) in an opening according to one or more embodiments.

FIG. 11F is a vertical cross-sectional view of an intermediate structure including the first dielectric filling layer on the die stack (first die stack) according to one or more embodiments.

FIG. 11G is a vertical cross-sectional view of an intermediate structure including the metal vias in the first dielectric filling layer according to one or more embodiments.

FIG. 11H is a vertical cross-sectional view of the completed package substrate having the fifth alternative configuration according to one or more embodiments.

FIG. 12 is a flow chart illustrating a method of making a package substrate according to one or more embodiments.

FIG. 13 is a vertical cross-sectional view of a package substrate having a sixth alternative configuration according to one or more embodiments.

FIG. 14 is a vertical cross-sectional view of a package structure including the package substrate according to one or more embodiments.

FIG. 15 is a vertical cross-sectional view of a package structure having an alternative configuration according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

In instances in which a die may be embedded within a package substrate, the feasibility of the manufacturing process may need to be taken into consideration. In particular, in instances in which the die is to be embedded in the core of the package substrate, a plated through hole (PTH) in the core may need to be removed. Since a PTH may be the only power path that may pass through the core, removing a plated through hole may result in a reduction in the number of power paths. A die embedded in the substrate may be unable to provide vertical power paths. Thus, embedding a die in the core may degrade a performance of power integrity in the package structure.

At least one embodiment of the present disclosure may include a package substrate including one or more embedded dies with one or more through-silicon-vias (TSVs). The dies may be embedded in a core of the package substrate and/or in the build-up portions on the core of the package substrate. The dies may include, for example, a new embedded component such as a die stack including a plurality of dies connected by a hybrid bond (e.g., wafer-to-wafer bond, SOIC bond). The die stack (e.g., vertically-bonded dies) may include a passive component and/or an active component, such as capacitor plus capacitor, capacitor plus IVR, etc.

The addition of TSV technology to the embedded die may provide a new path for power supply in the package substrate. This may help to reduce the impact of removing a plated through hole. In addition, embedding a stack of dies connected by a hybrid bond may allow for adjusting an overall height of the die, which may greatly increase the feasibility of embedding.

In some embodiments disclosed herein, one or more TSVs may be added to create an embedded die. Hybrid bonds may be used to combine multiple dies to form a larger embedded component (e.g., a die stack). The die including the TSVs may be embedded in a package substrate (e.g., a core of a package substrate).

The one or more embodiments may provide several advantages. In particular, by providing the embedded die with TSVs, a new vertical power path may be created. The new vertical power path may help to reduce horizontal fan-out paths. The die may be flexibly embedded into advanced packages such as by embedding a die stack that makes it easier to adjust a height of the embedded component. Further, the die stack may include a hybrid bond to enhance component characteristics, such as capacitance value rise, IVR plus capacitor, etc.

At least one or more embodiments may include a package structure (e.g., chip-on-wafer-on-substrate) including a top die connected to a package substrate by one or more C4 bumps. The package substrate may include a core, one or more plated through holes (PTH), and an Ajinomoto build-up (ABF) including metal (e.g., copper) traces and metal vias. The package structure may also include a ball grid array (BGA), an ABF filling (e.g., dielectric filling layer) and one or more dies embedded in the ABF filling. In at least one embodiment, the package structure may one or more layers of prepreg material (composite materials made of pre-impregnated reinforcing fibers and partially cured polymer matrix) on the core.

In at least one embodiment, the die may include a single embedded through silicon via (TSV) die including one or more TSVs (e.g., TSV technology). The TSVs may include a liner (e.g., insulating layer). The die may include a device region that includes one or more active devices and/or passive devices (e.g., transistors, deep trench capacitors (DTCs), etc.). The dies may include one or more microbumps for allowing the dies to be mounted on one or more metal pads, metal plane, metal contacts, etc. The dies may include a dielectric layer (e.g., dielectric molding) and one or more metal pads (e.g., copper pads; bonding pads) in the dielectric layer. The metal pads may contact the TSVs. In at least one embodiment, the die may include a die stack including a combination of multiple embedded TSV dies. In at least one embodiment, the die stack may include a hybrid bond (e.g., SOIC) bond between the dies in the die stack. The hybrid bond may include a bond between the bonding pads and the dielectric layers of the dies in the die stack.

The hybrid bond may have a thickness less than about 5 μm. A single die may have a thickness in a range from 50 μm to 650 μm. Combining multiple embedded TSV dies may be used to suit a desired embedding height. The die may include a passive component (e.g., capacitor, inductor, resistor, etc.) or an active component (e.g., transistor, integrated voltage regulator, etc.). The TSV die may be embedded in the core or prepreg material of the package substrate. In at least one embodiment, a size (e.g., lateral dimension) of the die may in a range from 2 mm×2 mm to 8 mm×8 mm. The package substrate may also include a keep-out zone between the core and embedded die. The keep-out zone may have a length in a range from 20 μm to 50 μm.

At least one embodiment may include a thick single-core substrate with a single embedded TSV die. A height of the die may be about the same as the core thickness. The core thickness may be selected to substantially equal the thickness of the die. With this configuration, the TSV may provide a new shorter power path to reduce horizontal fan-out paths, and the PI performance may be improved.

At least one embodiment may include one or more hybrid bonds to form a die stack (e.g., combined multiple dies) to form larger embedded components. The dies may include a single core substrate embedded die with TSV. The multiple dies may be connected by the hybrid bond (e.g., wafer-on-wafer bond). A thickness and quantity of the dies may be adjusted to match the core thickness. The core thickness may be about 1400 μm and multiple dies may be used to combine the total die height of 1400 μm. With this configuration, the TSV may provide a new shorter power path to reduce horizontal fan-out paths, the PI performance may be improved, and embedded die characteristics (e.g., capacitance increase, DTC+IVR, etc.) may be enhanced.

At least one embodiment may include a package substrate with two or more stacked cores. The stacked cores may be asymmetrical (e.g., different thicknesses, different location of through vias, etc.). In this case, a single die may be embedded in an upper substrate core of the stacked cores. Stacking multiple cores may help to increase rigidity of the package substrate. The embedded die may be placed in the upper core. The die may include one or more solder balls (e.g., microbumps) on the back of the die to connect to the lower core of the stacked cores. The shorter PTH may connect the die and BGA side. The height of a single die, upper core and lower core thickness may be about 650 μm. With this configuration, the TSV may provide a new shorter power path to reduce horizontal fan-out paths, the PI performance may be improved, and structural rigidity of the package substrate may be retained.

At least one embodiment may include a single embedded die in a core stack including asymmetrical cores (e.g., two stacked cores having one or more different features). The stacking of cores may help to increase rigidity of the package substrate. A thickness of the upper core may be less than a thickness of the lower core. An embedded die may be placed in the upper core and a build-up portion on the upper core. The die may include solder balls (e.g., microbumps) on the back of the die to connect to the lower core. The asymmetrical cores may enable the embedded die to be closer to the top die. The upper core thickness may be about 50 μm and the lower core thickness may be about 1350 μm. With this configuration, the TSV in the die may provide a new shorter power path to reduce horizontal fan-out paths. Further, the PI performance may be improved and structural rigidity of the package substrate may be retained.

At least one embodiment may include a package substrate with stacked cores, a single embedded die the upper core and a single embedded die in the lower core. Solder balls (e.g., microbumps) may be formed on the back of the dies to connect to the metal between the stacked cores. This configuration may increase core area usage. The height of a single die, an upper core thickness and lower core thickness may each be in a range from 50 μm to 650 μm (e.g., about 650 μm). With this configuration, the TSV may provide a new shorter power path to reduce horizontal fan-out paths. The configuration may also allow for a greater density of embedded components. Further, the PI performance may be improved and structural rigidity of the package substrate may be retained.

At least one embodiment may include embedded multiple dies into the build-up portion of the package substrate. In particular, the package substrate may include a substrate having a single core with a thickness of about 1400 μm. Multiple embedded dies may be placed on the build-up portion. The dies may be arranged back-to-back to form a packages substrate having a symmetrical structure. The height of a single die may be in a range from 50 μm to 200 μm. With this configuration, the TSV may provide a new shorter power path. The configuration may also allow for a greater density of embedded components. Further, the PI performance may be improved and structural rigidity of the package substrate may be retained.

At least one embodiment may include embedded multiple dies in the build-up portion and core of the package substrate. The package substrate may include a single core with thickness of about 1400 μm. Multiple embedded dies may be placed on the build-up portion and the substrate core. The dies may be arranged back-to-back so as to form a package substrate having a symmetrical structure. The height of a single die may be in a range from 50 μm to 200 μm. With this configuration, the TSV can provide a new shorter power path. The configuration may also allow for a greater density of embedded components. Further, the PI performance may be improved and structural rigidity of the package substrate may be retained.

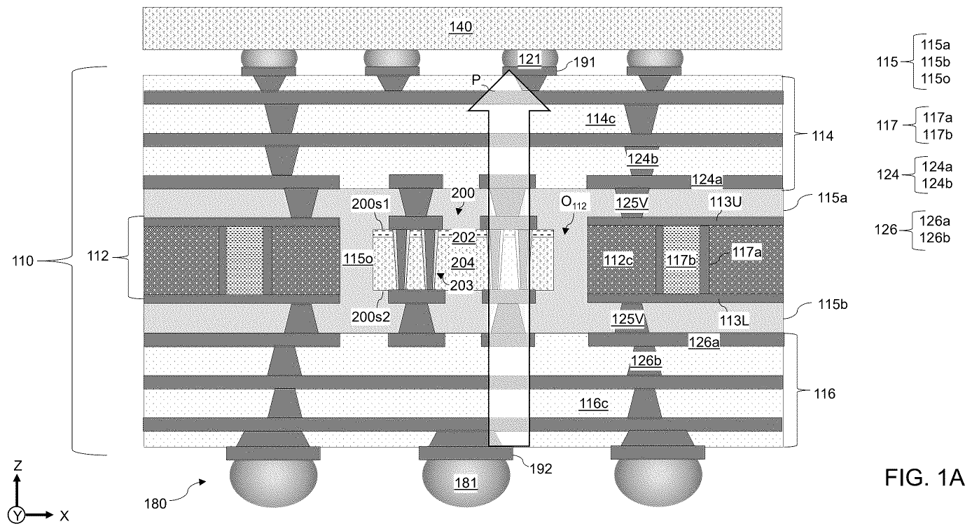

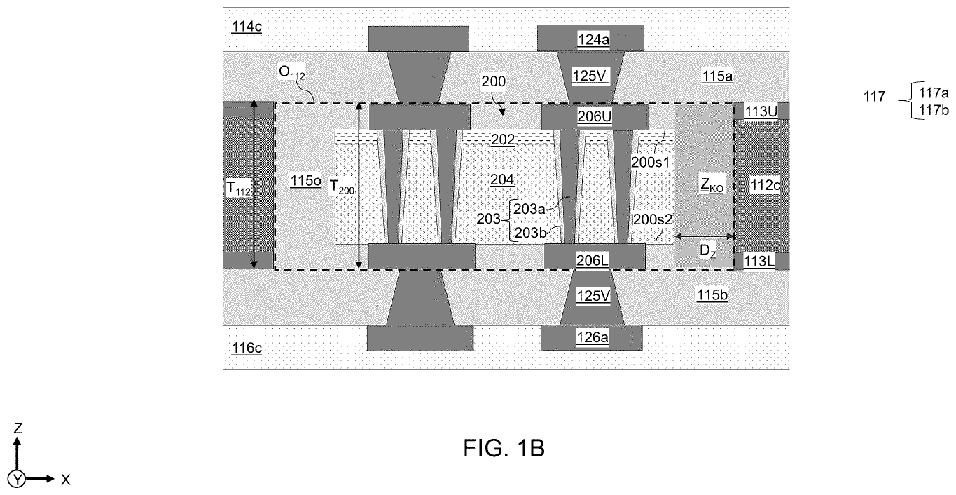

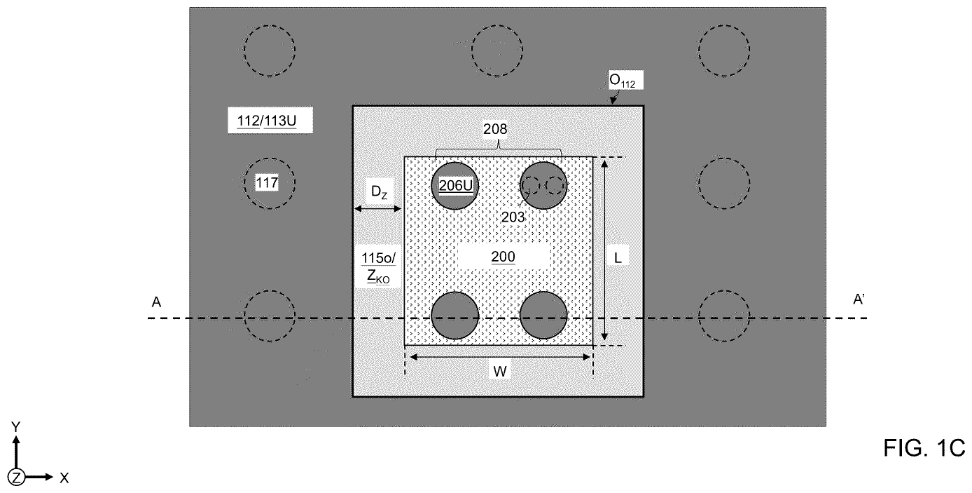

FIG. 1A is a vertical cross-sectional view of a package substrate 110 according to one or more embodiments. As illustrated in FIG. 1A, the package substrate 110 may include a core 112 located in a central region of the package substrate 110. The package substrate 110 may further include a dielectric filling layer 115 on the core 112 and/or in the core 112. The package substrate 110 may also include one or more dies 200 in the dielectric filling layer 115. The die 200 may include one or more through silicon vias (TSV) 203 extending from a first side 200s1 of the die 200 to a second side 200s2 of the die 200 opposite the first side 200s1 of the die 200. The die 200 may also include a device region 202 on the first side 200s1 of the die 200. The device region 202 may include, for example, a passive component (e.g., capacitor) and/or an active component (e.g., transistor). In at least one embodiment, the die 200 may include an integrated passive device (IPD).

As further illustrated in FIG. 1A, in at least one embodiment, the die 200 may be embedded in a core opening O₁₁₂ of the core 112. The die 200 may additionally or alternatively be located on the top side of the core 112 (e.g., a chip side of the core 112) or the bottom side of the core 112 (e.g., a board side of the core 112). The die 200 may include, for example, an embedded component such as a die stack (not shown) including a plurality of dies. The plurality of dies in the die stack may be connected by a hybrid bond (e.g., wafer-to-wafer bond, SOIC bond). The die stack (e.g., vertically-bonded dies) may include a passive component and/or an active component, such as capacitor plus capacitor, capacitor plus IVR, etc.

The addition of the TSV 203 (e.g., TSV technology) to the die 200 may provide a new path for power supply in the package substrate 110. This may mitigate the impact of removing a plated through hole in the core 112. In addition, in instances in which the die 200 includes a die stack (e.g., a plurality of dies connected by a hybrid bond), an overall height of the die 200 may be adjusted (e.g., by adding more or fewer dies to the die stack) which may greatly increase the feasibility of embedding the die 200 in the package substrate 110. In particular, the die 200 may be flexibly embedded into advanced packages by embedding the die stack. In addition, the hybrid bond may help to enhance component characteristics, such as capacitance value rise, IVR plus capacitor, etc.

The die 200 with one or more TSVs 203 may also help to provide a new power path P in the package substrate 110. In particular, the TSVs 203 may constitute at least a portion of the new power path P. The new power path P may be a substantially direct path (e.g., straight-line path) and may help to reduce a need for horizontal fan-out paths in the package substrate 110. The new power path P may, therefore, have a reduced length compared to the power paths in other package substrates. With this configuration, the package substrate 110 may have an improved PI performance while retaining a structural rigidity of the package substrate 110.

Referring again to FIG. 1A, the core 112 may enhance the rigidity to the package substrate 110. The core 112 may include, for example, a core central portion 112c which may constitute a primary thickness of the core 112. The core central portion 112c may be composed of an epoxy resin, a thermosetting resin such as bismaleimide-triazine resin (BT resin), polyimide and/or a ceramic material (e.g., alumina, aluminum nitride). Other suitable dielectric materials are within the contemplated scope of disclosure.

The core central portion 112c may also include a sheet of reinforcement material (not shown) embedded therein. The sheet of reinforcement material may include, for example, a fiberglass cloth sheet (e.g., woven fiberglass cloth sheet). In at least one embodiment, the core central portion 112c may include a fiberglass cloth sheet embedded in a resin such as an epoxy resin (e.g., FR-4). The core central portion 112c may include, for example, a woven fiberglass sheet laminate.

The core 112 may also include an upper conductive layer 113U on a top side of the core central portion 112c. The core 112 may also include a lower conductive layer 113L on a bottom side of the core central portion 112c. Each of the upper conductive layer 113U and the lower conductive layer 113L may include metals, metal alloys, and/or other metal-containing compounds (e.g., Cu, Al, Mo, Co, Ru, W, TiN, TaN, WN, etc.). Other suitable conductive materials are within the contemplated scope of disclosure.

The core 112 may also include one or more through vias 117 (e.g., plated through vias). The through vias 117 may extend from a lower surface of the core central portion 112c to an upper surface of the core central portion 112c. The through vias 117 may contact the upper conductive layer 113U on the top side of the core central portion 112c and the lower conductive layer 113L on the bottom side of the core central portion 112c.

The through vias 117 may include, for example, plated through holes (PTHs). In particular, the through holes may include a metal plating 117a around the outer periphery of the through holes and an inner portion 117b surrounded by the metal plating 117a. The metal plating 117a may include metals, metal alloys, and/or other metal-containing compounds (e.g., Cu, Al, Mo, Co, Ru, W, TiN, TaN, WN, etc.). Other suitable metal materials are within the contemplated scope of disclosure. The inner portion 117b may remain substantially hollow (e.g., containing only air). The inner portion 117b may alternatively or additionally be filled with a conductive material such as conductive epoxy or copper paste or a non-conductive material such as a non-conductive epoxy or other dielectric material. The inner portion 117b may alternatively include conductive material such as metals, metal alloys, and/or other metal-containing compounds (e.g., Cu, Al, Mo, Co, Ru, W, TiN, TaN, WN, etc.).

As illustrated in FIG. 1A, the core 112 may also include a core opening O₁₁₂. The core opening O₁₁₂ may extend vertically through an entire thickness of the core 112 (e.g., through the core central portion 112c, the upper conductive layer 113U and the lower conductive layer 113L).

The dielectric filling layer 115 may include a dielectric filling layer upper portion 115a on the upper conductive layer 113U on the top side of the core 112. The dielectric filling layer 115 may also include a dielectric filling layer lower portion 115b on the lower conductive layer 113L on the bottom side of the core 112. The dielectric filling layer 115 may also include a dielectric filling layer opening portion 115o formed in the core opening O₁₁₂. The dielectric filling layer opening portion 115o may substantially fill the core opening O₁₁₂ and may connect the dielectric filling layer upper portion 115a to the dielectric filling layer lower portion 115b. In at least one embodiment, the die 200 may be located in (e.g., embedded in) the dielectric filling layer opening portion 115o in the core opening O₁₁₂.

The dielectric filling layer 115 may include one or more layers of dielectric material. In at least one embodiment, the dielectric filling layer 115 may include ABF filling material. The dielectric filling layer 115 may additionally or alternatively include a dielectric polymer material such as polyimide (PI), benzocyclobutene (BCB), or polybenzobisoxazole (PBO). Other suitable dielectric materials are within the contemplated scope of disclosure.

One or more metal vias 125V may be formed on the upper conductive layer 113U in the dielectric filling layer upper portion 115a. One or more metal vias 125V may also be formed on the lower conductive layer 113L in the dielectric filling layer lower portion 115b. The metal vias 125V may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate 110 may also include an upper build-up portion 114 on the top side of the core 112. The upper build-up portion 114 may include a plurality of dielectric layers 114c. The dielectric layers 114c may be composed of a build-up film such as Ajinomoto build-up film (ABF). The dielectric layers 114c may alternatively or additionally include an organic material such as a polymer material. In particular, the upper build-up portion 114 may include a plurality of layers including dielectric polymer material such as polyimide (PI), benzocyclobutene (BCB), or polybenzobisoxazole (PBO). Other suitable dielectric materials are within the contemplated scope of disclosure.

The upper build-up portion 114 may also include a metal interconnect structure 124 in the plurality of dielectric layers 114c. The metal interconnect structure 124 may include a redistribution layer (RDL) structure. The metal interconnect structure 124 may include metal layers 124a (e.g., copper traces) and metal vias 124b connecting the metal layers 124a. The metal layers 124a may be alternatingly formed with the plurality of dielectric layers 114c. The metal interconnect structure 124 may be electrically coupled to the upper conductive layer 113U and the through vias 117 in the core 112 by the metal vias 125V in the dielectric filling layer upper portion 115a.

The metal interconnect structure 124 may include an uppermost metal layer 124a and an uppermost metal via 124b on the uppermost metal layer 124a. The package substrate 110 may include one or more upper bonding pads 191 on the upper surface of the upper build-up portion 114. The upper bonding pads 191 may contact the uppermost metal via 124b. The upper bonding pads 191 may, therefore, be electrically coupled to the through vias 117 in the core 112 by the metal interconnect structure 124, the metal vias 125V in the dielectric filling layer upper portion 115a and the upper conductive layer 113U. The upper bonding pads 191 may have a width greater than the width of the uppermost metal vias 124b. The upper bonding pads 191 may be configured to serve as a mounting surface for solder bumps 121 (e.g., C4 bumps). In at least one embodiment, one or more top dies 140 may be mounted on the upper bonding pads 191 by the solder bumps 121. Each of the metal interconnect structure 124 and the upper bonding pads 191 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate 110 may also include an upper solder resist layer (not shown) on the upper surface of the upper build-up portion 114. The upper solder resist layer may include a thin layer of polymer material (e.g., epoxy polymer). The upper solder resist layer may have a thickness in a range from about 5 μm to 50 μm. In at least one embodiment, the upper solder resist layer may have a thickness in a range from about 10 μm to 30 μm. Greater or lesser thickness of the upper solder resist layer may be used.

The upper solder resist layer may be formed so as to cover the upper bonding pads 191 and other metal features (e.g., conductive lines, copper traces) on the upper surface of the upper build-up portion 114. The upper solder resist layer may protect the upper bonding pads 191 and other metal features from oxidation. The upper solder resist layer may also prevent solder bridges (e.g., unintended electrical connections) from forming between closely spaced metal features.

The package substrate 110 may also include a lower build-up portion 116 on the bottom side of the core 112. The through vias 117 in the core 112 may provide an electrical connection between the upper build-up portion 114 and the lower build-up portion 116. The lower build-up portion 116 may include a plurality of dielectric layers 116c. The dielectric layers 116c may be composed of a build-up film such as Ajinomoto build-up film (ABF). The dielectric layers 116c may alternatively or additionally include an organic material such as a polymer material. In particular, the lower build-up portion 116 may include a plurality of layers including dielectric polymer material such as polyimide (PI), benzocyclobutene (BCB), or polybenzobisoxazole (PBO). Other suitable dielectric materials are within the contemplated scope of disclosure.

The lower build-up portion 116 may also include a metal interconnect structure 126 in the plurality of dielectric layers 114c. The metal interconnect structure 126 may include a redistribution layer (RDL) structure. The metal interconnect structure 126 may include metal layers 126a (e.g., copper traces) and metal vias 126b connecting the metal layers 126a. The metal layers 126a may be alternatingly formed with the plurality of dielectric layers 114c. The metal interconnect structure 126 may be electrically coupled to the lower conductive layer 113L and the through vias 117 in the core 112 by the metal vias 125V in the dielectric filling layer lower portion 115b.

The metal interconnect structure 126 may include a lowermost metal layer 126a and a lowermost metal via 126b on the lowermost metal layer 126a. The package substrate 110 may include one or more lower bonding pads 192 on the lower surface of the lower build-up portion 116. The lower bonding pads 192 may contact the lowermost metal via 126b. The lower bonding pads 192 may, therefore, be electrically coupled to the through vias 117 in the core 112 by the metal interconnect structure 126, the metal vias 125V in the dielectric filling layer lower portion 115b and the lower conductive layer 113L. The lower bonding pads 192 may have a width greater than the width of the lowermost metal vias 126b. The lower bonding pads 192 may be configured to serve as a mounting surface for solder balls 181 of a ball grid array (BGA) 180 formed on the lower surface of the lower build-up portion 116. Each of the metal interconnect structure 126 and the lower bonding pads 191 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

In at least one embodiment, the metal interconnect structure 124 in the upper build-up portion 114 on the top side of the core 112 may be electrically coupled to the TSV 203 in the die 200. The metal interconnect structure 126 in the lower build-up portion 116 on the bottom side of the core 112 may be electrically coupled to the TSV 203 in the die 200. Therefore, the top die 140 mounted on the upper bonding pads 191 on the top side of the package substrate 110 may be electrically coupled to the BGA 180 formed on the lower bonding pads 192 on the bottom side of the package substrate 110 through the TSV 203 in the die 200. This configuration may help to allow the TSV 203 in the die 200 to serve as part of a new power path in the package substrate 110.

The package substrate 110 may also include a lower solder resist layer (not shown) on the lower surface of the lower build-up portion 116. The lower solder resist layer may include a thin layer of polymer material (e.g., epoxy polymer). The lower solder resist layer may have a thickness in a range from about 5 μm to 50 μm. In at least one embodiment, the lower solder resist layer may have a thickness in a range from about 10 μm to 30 μm. Greater or lesser thickness of the lower solder resist layer may be used.

The lower solder resist layer may be formed so as to cover the lower bonding pads 192 and other metal features (e.g., conductive lines, copper traces) on the lower surface of the lower build-up portion 116. The lower solder resist layer may protect the lower bonding pads 192 and other metal features from oxidation. The lower solder resist layer may also prevent solder bridges (e.g., unintended electrical connections) from forming between closely spaced metal features.

FIG. 1B is a detailed vertical cross-sectional view of a portion of the package substrate 110 including the die 200 according to one or more embodiments. As illustrated in FIG. 1B, the die 200 may be substantially centrally located in the core opening O₁₁₂. The package substrate 110 may also include a keep-out zone Z_{KO} between the core 112 and the die 200. The keep-out zone Z_{KO} may generally occupy the same space as the dielectric filling layer opening portion 115o. The keep-out zone Z_{KO} may have a width D_{z} in a range from 20 μm to 50 μm. Other widths of the keep-out zone Z_{KO} are within the contemplated scope of disclosure.

The die 200 may include a bulk semiconductor region 204 (e.g., bulk silicon region) on the second side 200s2 of the die 200. The bulk semiconductor region 204 may adjoin the device region 202 of the die 200. A thickness of the bulk semiconductor region 204 may be greater than a thickness of the device region 202 of the die 200.

The die 200 may also include an upper die bonding pad 206U on the first side 200s1 of the die 200. A metal via 125V in the dielectric filling layer upper portion 115a may contact an upper surface of the upper die bonding pad 206U. A metal layer 124a in the metal interconnect structure 124 of the upper build-up portion 114 may contact an upper surface of the metal via 125V.

The die 200 may also include a lower die bonding pad 206L on the second side 200s2 of the die 200. A metal via 125V in the dielectric filling layer lower portion 115b may contact a lower surface of the lower die bonding pad 206L. A metal layer 126a in the metal interconnect structure 126 of the lower build-up portion 116 may contact a lower surface of the metal via 125V.

The upper die bonding pad 206U and die lower bonding pad 206L may each have a thickness in a range from 2 μm to 40 μm. Other thicknesses are within the contemplated scope of disclosure. The upper die bonding pad 206U and die lower bonding pad 206L may each include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

In at least one embodiment, a thickness T₂₀₀ of the die 200 including the upper die bonding pad 206U and die lower bonding pad 206L may be in a range from 50 μm to 650 μm. The thickness T₂₀₀ of the die 200 may be substantially the same as a thickness T₁₁₂ of the core 112. In at least one embodiment, a size (e.g., lateral dimension in the x-direction and y-direction) of the die 200 may in a range from 2 mm×2 mm to 8 mm×8 mm. Other thicknesses and lateral dimensions of the die 200 are within the contemplate scope of disclosure.

As further illustrated in FIG. 1B, a pair of TSVs 203 may connect an upper die bonding pad 206U to a lower die bonding pad 206L. However, more or fewer TSVs 203 may be used to connect an upper die bonding pad 206U to a lower die bonding pad 206L. A number and/or size of the TSVs 203 in the die 200 should be sufficient to serve as a power supply path in the package substrate 110. In particular, the power transmitting ability (e.g., current-carrying capacity or ampacity) of the TSVs 203 in the die 200 may approximate the power transmitting ability of the through vias 117 removed by forming the core opening O₁₁₂ in the core 112. Thus, in embodiments in which a material of the TSVs 203 is substantially the same as a material of the through vias 117 (e.g., having substantially the same electrical conductivity), a volume of the conductive material in the TSVs 203 in the die 200 may be substantially the same as a volume of the conductive material in the removed through vias 117.

The TSVs 203 may include a conductive inner portion 203a. The conductive inner portion 203a may electrically couple the upper die bonding pad 206U to the lower die bonding pad 206L. The conductive inner portion 203a may have a substantially tapered shape. The conductive inner portion 203a may have a substantially circular horizontal cross-sectional shape. Other horizontal cross-sectional shapes are within the contemplated scope of disclosure. The conductive inner portion 203a may have a cross-sectional diameter that decreases in a direction towards the second side 200s2 of the die 200. The cross-sectional diameter of the conductive inner portion 203a may be in a range from 2 μm to 50 μm at the first side 200s1 of the die 200. The cross-sectional diameter of the conductive inner portion 203a may be in a range from 0.5 μm to 35 μm at the second side 200s2 of the die 200.

The conductive inner portion 203a may have a length in the z-direction that is substantially the same as a distance between the first side 200s1 of the die 100 and the second side 200s2 of the die. The conductive inner portion 203a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The TSV 203 may also include an insulating liner 203b around the conductive inner portion 203a. The insulating liner 203b may be formed on a wall of an opening in which the TSV 203 is formed. The insulating liner 203b may surround an entirety of the conductive inner portion 203a. In at least one embodiment, the insulating liner 203b may completely insulate the conductive inner portion 203a from the portion of the die 200 surrounding the TSV 203. The insulating liner 203b may be formed, for example, of dielectric material such as silicon dioxide, silicon nitride, or a polymer-based dielectric like benzocyclobutene (BCB). Other suitable materials may be used for the insulating liner 203b.

The die 200 embedded in the package substrate 110 may be used for substantially the same or different applications than applications for use of the top die 140 mounted on the package substrate 110. In particular, each of the die 200 and the top die 140 may include, for example, a singular semiconductor die structure, a system on chip die, or a system on integrated chips die, and may be implemented by chip-on-wafer-on-substrate technology or integrated fan-out on substrate technology. In particular, each of the die 200 and the top die 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., HBM die, hybrid memory cube (HMC), dynamic random access memory (DRAM) die, a Wide I/O die, a M-RAM die, a R-RAM die, a NAND die, static random access memory (SRAM), etc. ), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the top die 140 may include a primary die (e.g., SOC die), and the embedded die 200 may include an ancillary die.

FIG. 1C is a detailed top-down view (e.g., plan view) of a portion of the package substrate 110 including the die 200 according to one or more embodiments. It should be noted that the portion of the package substrate 110 above the core 112 has been omitted in FIG. 1C for ease of understanding. The vertical cross-sectional view in FIG. 1A is the view along lines A-A′ in FIG. 1C.

As illustrated in FIG. 1C, the die 200 may have a substantially square shape in the top-down view. Other shapes are within the contemplated scope of disclosure. The die 200 may have a length L in the y-direction and a width W in the x-direction that is substantially the same as the length L. Each of the length L and the width W may be in a range from 2 mm to 8 mm.

A center of the die 200 may be substantially aligned with a center of the core opening O₁₁₂. A shape (e.g., square shape) of the core opening O₁₁₂ may be substantially the same as the shape of the die 200. The width Dz of the keep-out zone Z_{KO} may be substantially uniform around the entire periphery of the die 200.

A location of the through vias 117 in the core 112 are shown by dashed lines in FIG. 1C. The through vias 117 may be formed in the core 112 in a two dimensional array having rows and columns. The die upper bonding pads 206U on the first side 200s1 of the die 100 may be substantially aligned with the through vias 117 in the core 112 in the x-direction. In at least one embodiment, the TSVs 203 contacting the die upper bonding pads 206U may be substantially aligned with the through vias 117 in the core 112 in the x-direction.

Each pair of the die upper bonding pads 206U adjacent in the x-direction may constitute a pad pair 208. The pad pairs 208 may be substantially aligned with the through vias 117 in the core 112 in the y-direction. In at least one embodiment, an upper surface of the die upper bonding pads 206U may have a substantially circular shape (in the top-down view). A shape of an upper surface of the through vias 117 may be substantially the same as the shape of the upper surface of the die upper bonding pads 206U.

In at least one embodiment, an area of the upper surface of each of the die upper bonding pads 206U may be equal to or greater than an area of the upper surface of a through via 117. Thus, the combined area of the upper surface of the die upper bonding pads 206U in a pad pair 208 may be at least twice the area of the upper surface of the through via 117. Further, a combined area of an upper surface of the TSVs 203 contacting the upper die bonding pad 206U may be at least 50% of the area of the upper surface of the upper die bonding pad 206U. This may help to ensure that a power transmitting ability of the TSVs 203 in a pad pair 208 (e.g., a total of four TSVs 203) may approximate a power transmitting ability of one through via 117. In at least one embodiment, the power transmitting ability of the four TSVs 203 in a pad pair 208 may be at least 90% of the power transmitting ability of one through via 117.

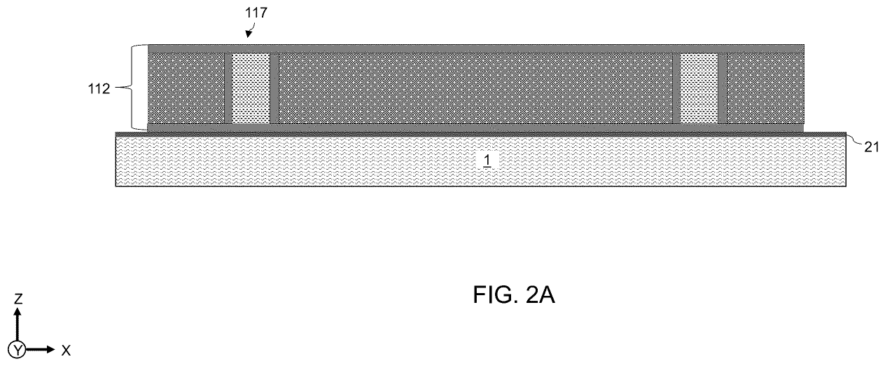

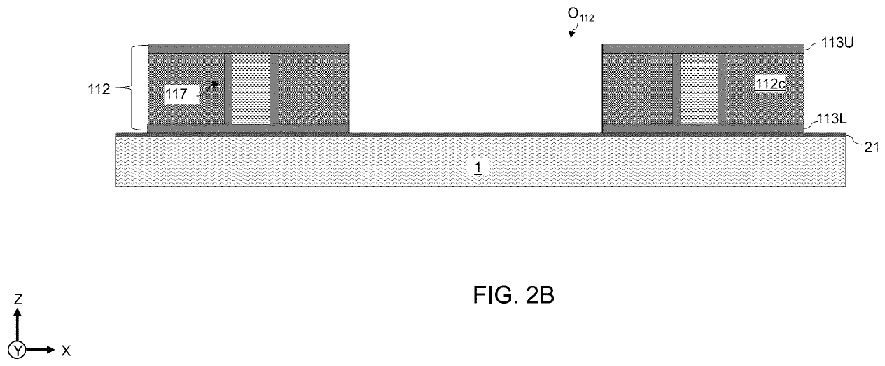

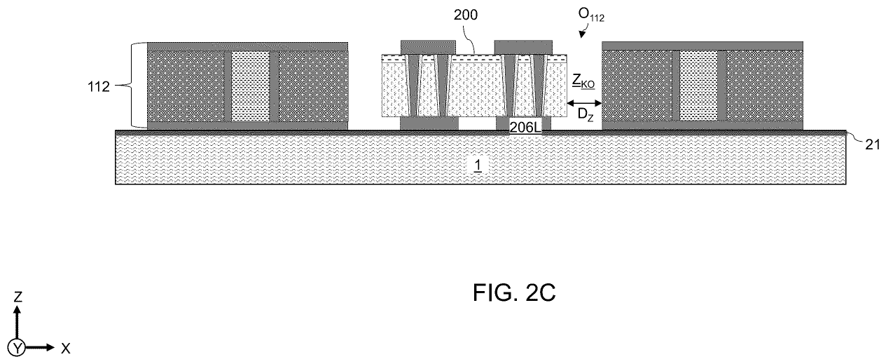

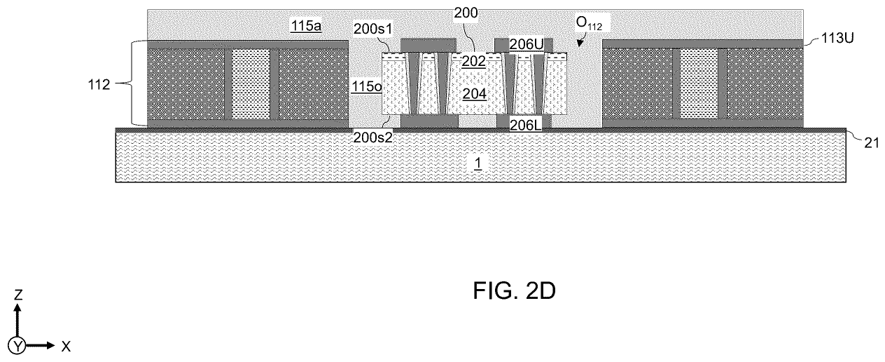

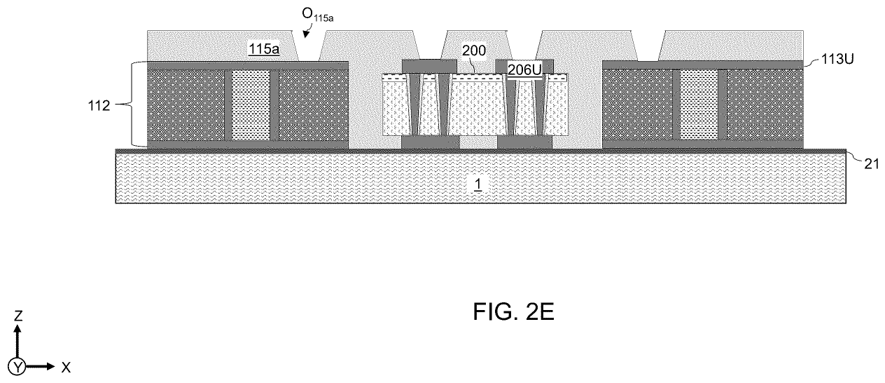

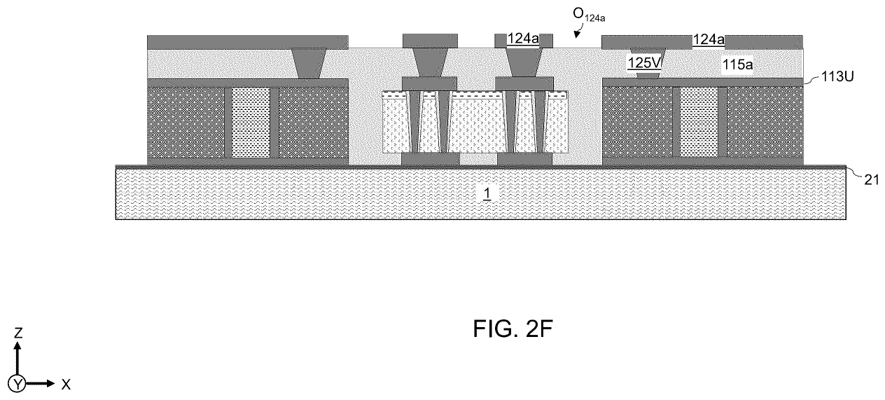

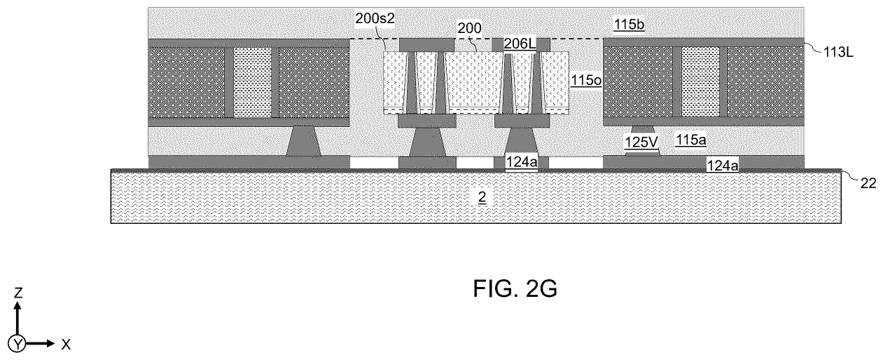

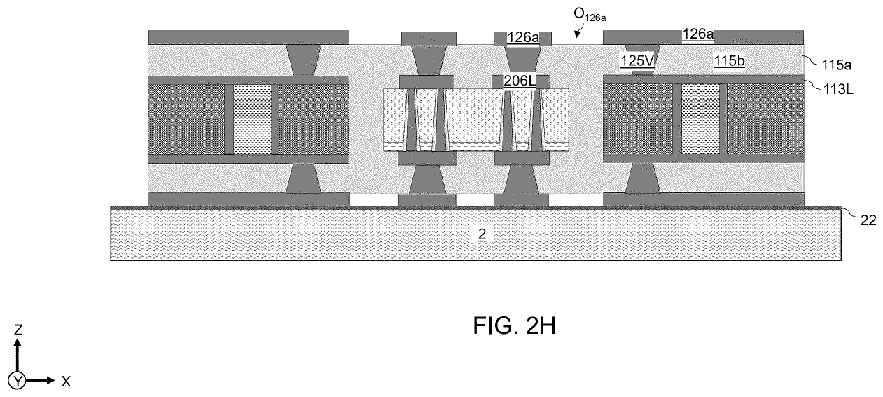

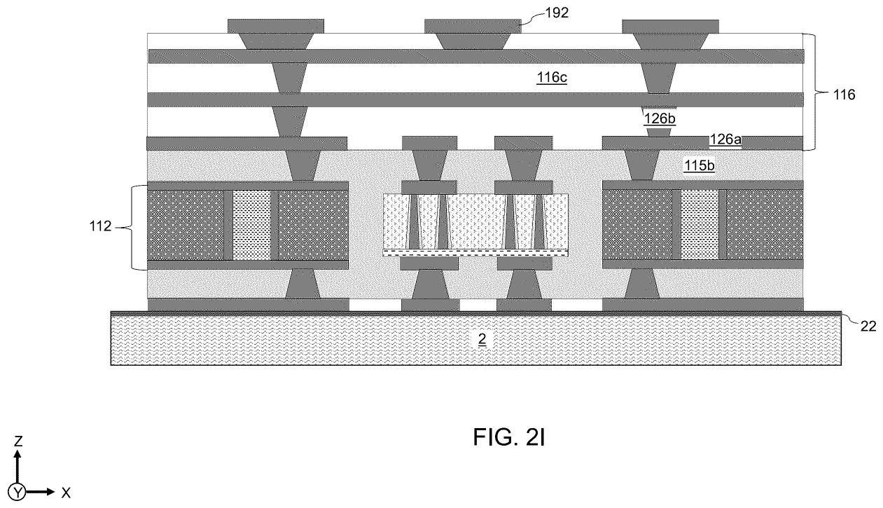

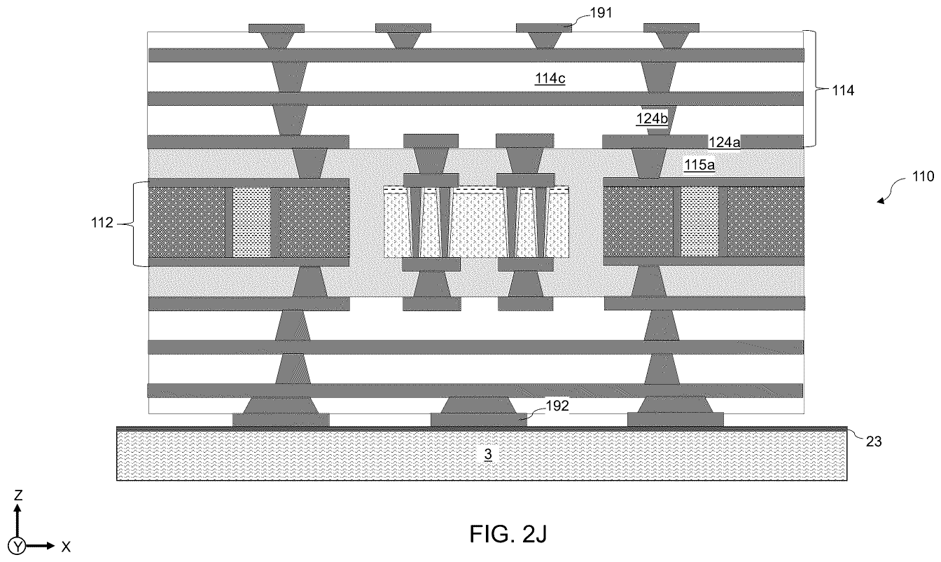

FIGS. 2A-2I are vertical cross-sectional views of intermediate structures in a method of making the package substrate 110 according to one or more embodiments.

FIG. 2A is a vertical cross-sectional view of an intermediate structure including the core 112 on a first carrier substrate 1 (e.g., carrier wafer) according to one or more embodiments. The core 112 may be placed on the first carrier substrate 1 by an electromechanical pick-and-place (PNP) machine.

The first carrier substrate 1 may be a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. The thickness of the first carrier substrate 1 may be sufficient to provide mechanical support to an array of interposers to be formed thereupon. For example, the thickness of the first carrier substrate 1 may be in a range from 60 microns to 1 mm, although lesser and greater thicknesses may also be used.

The core 112 may be removably attached to the first carrier substrate 1 by an adhesive layer 21 applied to a top surface of the first carrier substrate 1. In one embodiment, the first carrier substrate 1 may include an optically transparent material such as glass or sapphire. In this embodiment, the adhesive layer 21 may include a light-to-heat conversion (LTHC) layer. The LTHC layer is a solvent-based coating applied using a spin-coating method. The LTHC layer may form a layer that converts ultraviolet light to heat such that the LTHC layer loses adhesion. Alternatively, the adhesive layer 21 may include a thermally decomposing adhesive material. For example, the adhesive layer 21 may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

FIG. 2B is a vertical cross-sectional view of an intermediate structure including the core opening O₁₁₂ in the core 112 according to one or more embodiments. The core opening O₁₁₂ may be formed by forming openings in the core central portion 112c (e.g., epoxy resin, woven glass laminate, etc.), the upper conductive layer 113U on the top side of the core central portion 112c, and the lower conductive layer 113L on the bottom side of the core central portion 112c. The core opening O₁₁₂ may be formed, for example, by a laser drilling process. The laser drilling process may use, for example, an ultraviolet (UV) laser (e.g., excimer laser) or CO₂ laser because these lasers may be precisely controlled and are effective at ablating dielectric materials without damaging surrounding areas.

The core opening O₁₁₂ may alternatively or additionally be formed by using a photolithographic process. The photolithographic process may include forming a patterned photoresist mask (not shown) on the upper conductive layer 113U and etching (e.g., wet etching, dry etching, etc.) the exposed portion of the core 112 through an opening in the photoresist mask. The photoresist mask may be subsequently removed by ashing, dissolving the photoresist mask or by consuming the photoresist mask during the etch process.

FIG. 2C is a vertical cross-sectional view of an intermediate structure including the die 200 in the core opening O₁₁₂ according to one or more embodiments. The die 200 may be placed in the core opening O₁₁₂ by an electromechanical pick-and-place (PNP) machine. The lower die bonding pad 206L of the die 200 may be attached to the first carrier substrate 1 by the adhesive layer 21.

In placing the die 200 in the core opening O₁₁₂, care may be taken to ensure that the center of the die 200 may be aligned with a center of the core opening O₁₁₂. In particular, care may be taken to ensure that the keep-out zone Z_{KO} having a width D_{Z} (e.g., in a range from 20 μm to 50 μm) may be formed around the periphery of the die 200 (e.g., see FIG. 1C).

FIG. 2D is a vertical cross-sectional view of an intermediate structure including a portion of the dielectric filling layer 115 on the die 200 according to one or more embodiments. After the die 200 has been placed in the core opening O₁₁₂, the dielectric filling layer upper portion 115a and dielectric filling layer opening portion 115o may be formed. The dielectric filling layer lower portion 115b may be formed in a subsequent step.

A layer of dielectric filling material (e.g., ABF) may be deposited on the upper conductive layer 113U of the core 112 and in the core opening O₁₁₂. The layer of dielectric filling material may be formed, for example, by at least one of spin-coating, lamination or other suitable methods (e.g., chemical vapor deposition (CVD), physical vapor deposition (PVD), etc.).

The layer of dielectric filling material may be formed so as to cover the exposed adhesive layer 21 in the core opening O₁₁₂. The layer of dielectric filling material may be formed under the second side 200s2 of the die 200 and around the lower die bonding pads 206L. The layer of dielectric filling material may also be formed on all of the sidewalls of the die 200, on the first side 200s1 of the die and around the upper die bonding pads 206U.

The layer of dielectric filling material may be formed so as to completely fill the core opening O₁₁₂. The layer of dielectric filling material may be formed so as to be substantially free of air bubbles. The layer of dielectric filling material may be formed on the upper conductive layer 113U to have a thickness that is substantially the same as the completed dielectric filling layer upper portion 115a in the package substrate 110.

The deposited layer of dielectric filling material may (e.g., depending upon the type of dielectric material) may be cured by a curing process. A first part of the curing process may include a pre-bake or soft bake (e.g., in a range from 80° C. to 120° C.) to evaporate any solvents and start the hardening of the layer. A second part of the curing process may include a high-temperature bake (e.g., in a range from 150° C. to 200° C. for a duration in a range of 30 minutes to 2 hours) to cross-link the polymers in the dielectric filling material (e.g., resin) and transform it into a hard, durable dielectric layer that may constitute the dielectric filling layer upper portion 115a and the dielectric filling layer opening portion 115o.

FIG. 2E is a vertical cross-sectional view of an intermediate structure including openings O₁₁₅ₐ (e.g., via holes) in the dielectric filling layer upper portion 115a according to one or more embodiments. After the dielectric filling layer upper portion 115a is formed, openings O₁₁₅ₐ may be formed in the dielectric filling layer upper portion 115a. The openings O₁₁₅ₐ may expose an upper surface of the upper die bonding pads 206U and an upper surface of the upper conductive layer 113U. In at least one embodiment, the openings O₁₁₅ₐ may be formed by a laser drilling process. The laser drilling process may use, for example, an ultraviolet (UV) laser (e.g., excimer laser) or CO2 laser because these lasers may be precisely controlled and are effective at ablating dielectric materials without damaging surrounding areas.

The openings O₁₁₅ₐ may alternatively or additionally be formed by using a photolithographic process. The photolithographic process may include forming a patterned photoresist mask (not shown) on the dielectric filling layer upper portion 115a and etching (e.g., wet etching, dry etching, etc.) the exposed upper surface of the dielectric filling layer upper portion 115a through openings in the photoresist mask. The photoresist mask may be subsequently removed by ashing, dissolving the photoresist mask or by consuming the photoresist mask during the etch process.

FIG. 2F is a vertical cross-sectional view of an intermediate structure including metal vias 125V in the dielectric filling layer upper portion 115a according to one or more embodiments. The metal vias 125V may be formed in the openings O₁₁₅ₐ. A metal layer 124a of the metal interconnect 124 may also be formed on the upper surface of the dielectric filling layer upper portion 115a in the same process used to form the metal vias 125V. In particular, the metal layer 124a and the metal vias 125V may be integrally formed as a unit.

The metal layer 124a and the metal vias 125V may be formed, for example, by an electroplating process. After the metal layer 124a and the metal vias 125V are formed, the metal layer 124a may be patterned to form the openings O₁₂₄ₐ in the metal layer 124a. The metal layer 124a may be patterned (forming the openings O₁₂₄ₐ) by using a photolithographic process. The photolithographic process may include forming a patterned photoresist mask (not shown) on the metal layer 124a and etching (e.g., wet etching, dry etching, etc.) the exposed upper surface of the metal layer 124a through openings in the photoresist mask. The photoresist mask may be subsequently removed by ashing, dissolving the photoresist mask or by consuming the photoresist mask during the etch process.

FIG. 2G is a vertical cross-sectional view of an intermediate structure including the dielectric filling layer lower portion 115b according to one or more embodiments. After the metal layer 124a is patterned, a second carrier substrate 2 may be placed an upper surface of the metal layer 124a. The second carrier substrate 2 may be substantially the same as the first carrier substrate 1. The second carrier substrate 2 may include an adhesive layer 22 similar to the adhesive layer 21 on the first carrier substrate 1. The metal layer 124a may be removably attached to the second carrier substrate 2 by the adhesive layer 22.

The intermediate structure may then be inverted (e.g., rotated, flipped) and placed on a stable surface. The intermediate structure may then be detached from the first carrier substrate 1. The first carrier substrate 1 may be detached from the intermediate structure, for example, by deactivating the adhesive layer 21 (see FIG. 2F) adhering the first carrier substrate 1 to the intermediate structure. The adhesive layer 21 may be deactivated, for example, by a thermal anneal at an elevated temperature (e.g., for a thermally-deactivated adhesive material, or by exposing the adhesive layer 21 to ultraviolet light (e.g., for an ultraviolet-deactivated adhesive material).

After the first carrier substrate 1 may be detached from the intermediate structure, the dielectric filling layer lower portion 115b may be formed. In at least one embodiment, the dielectric filling layer lower portion 115b may be formed by a process similar to the process of forming the dielectric filling layer upper portion 115a and dielectric filling layer opening portion 115o (e.g., see FIG. D). In particular, a layer of dielectric filling material (e.g., ABF) may be deposited on the lower conductive layer 113L, a surface of the dielectric filling layer opening portion 115o (indicated by a dashed line in FIG. 2G), the second side 200s2 of the die 200 and the lower die bonding pads 206L. The layer of dielectric filling material may be formed, for example, by at least one of spin-coating, lamination or other suitable methods (e.g., CVD, PVD, etc.).

FIG. 2H is a vertical cross-sectional view of an intermediate structure including metal vias 125V in the dielectric filling layer lower portion 115b and a metal layer 126a on the dielectric filling layer lower portion 115b according to one or more embodiments. The process of forming the metal vias 125V and metal layer 126a may be substantially the same as the process for forming the metal vias 125V and the metal layer 124a described above.

Openings (via holes; not shown) may be formed in the dielectric filling layer lower portion 115a. The openings may expose a surface of the lower die bonding pads 206L and a surface of the lower conductive layer 113L. In at least one embodiment, the openings may be formed by a laser drilling process. The openings may alternatively or additionally be formed by using a photolithographic process.

The metal vias 125V may be formed in the openings. A metal layer 126a of the metal interconnect 126 may also be formed on the surface of the dielectric filling layer lower portion 115b in the same process used to form the metal vias 125V. In particular, the metal layer 126a and the metal vias 125V may be integrally formed as a unit. The metal layer 126a and the metal vias 125V may be formed, for example, by an electroplating process. Other suitable processes may be used to form the metal layer 126a and the metal vias 125V.

The metal layer 126a may be patterned to form the openings O₁₂₆ₐ in the metal layer 126a. The metal layer 126a may be patterned (forming the openings O₁₂₆ₐ) by using a photolithographic process. The photolithographic process used to form the openings O₁₂₆ₐ may be substantially the same as the photolithographic process used to form the openings O₁₂₄ₐ (see FIG. 2F).

FIG. 2I is a vertical cross-sectional view of an intermediate structure including the lower build-up portion 116 according to one or more embodiments. The lower build-up portion 116 may be formed on the core 112 over the metal layer 126a that are patterned on the dielectric filling layer lower portion 115b. The lower build-up portion 116 may be formed by a process that includes alternatingly depositing the dielectric layers 116c (e.g., a build-up film such as ABF) and forming the metal interconnect structure 126 (e.g., metal layers 126a and metal vias 126b) in and on the dielectric layers 116c.

The build-up process may begin with the forming of a dielectric layer 116c by spin-coating, lamination or other suitable process (e.g., CVD, PVD, etc.). A photolithographic process may then be used to pattern the dielectric layer 116c to define the locations where the metal layers 126a will be formed. The photolithographic process may include forming a patterned photoresist mask (not shown) on the dielectric layer 116c and etching (e.g., wet etching, dry etching, etc.) the exposed upper surface of the dielectric layer 116c through openings in the photoresist mask. The photoresist mask may be subsequently removed by ashing, dissolving the photoresist mask or by consuming the photoresist mask during the etch process. Via holes may also be formed in the dielectric layer 116c at locations where the metal vias 126b may be subsequently formed. The via holes may be formed by laser drilling (using a UV laser for fine via holes or a CO₂ laser for larger via holes) or other suitable process (e.g., etching). A layer of metal material may then be deposited (e.g., by electroplating, CVD or other suitable method) on the etched surface of the dielectric layer 116c and in the via holes to form the metal layers 126a and the metal vias 126b, respectively. Planarization by chemical mechanical polishing (CMP) or other suitable method may then be performed to remove excess metal material on the surface of the dielectric layer 116c. The lower bonding pads 192 may be formed together with the lowermost metal via 126b in the process of forming the lower build-up portion 116.

FIG. 2J is a vertical cross-sectional view of an intermediate structure including the upper build-up portion 114 according to one or more embodiments. A third carrier substrate 3 may be placed an upper surface of the formed lower bonding pads 192. The third carrier substrate 3 may be substantially the same as the first carrier substrate 1 and second carrier substrate 2. The third carrier substrate 3 may include an adhesive layer 23 similar to the adhesive layer 21 on the first carrier substrate 1 and the adhesive layer 22 on the second carrier substrate 2. The lower bonding pads 192 may be removably attached to the third carrier substrate 3 by the adhesive layer 23.

The intermediate structure may then be inverted (e.g., rotated, flipped) and placed on a stable surface. The intermediate structure may then be detached from the second carrier substrate 2. The second carrier substrate 2 may be detached from the intermediate structure, for example, by deactivating the adhesive layer 22 adhering the second carrier substrate 2 to the intermediate structure. The adhesive layer 22 may be deactivated, for example, by a thermal anneal at an elevated temperature (e.g., for a thermally-deactivated adhesive material, or by exposing the adhesive layer 22 to ultraviolet light (e.g., for an ultraviolet-deactivated adhesive material).

After the second carrier substrate 2 is detached from the intermediate structure, the upper build-up portion 114 may be formed on the core 112. The upper build-up portion 114 may be formed by a process similar to the process used to form the lower build-up portion 116 (see FIG. 2I). The process may include alternatingly depositing the dielectric layers 114c and forming the metal layers 124a and metal vias 124b in and on the dielectric layers 114c. In particular, a dielectric layer 114c may be formed by spin-coating, lamination or other suitable process (e.g., CVD, PVD, etc.). A photolithographic process may then be used to pattern the dielectric layer 114c to define the locations where the metal layers 124a will be formed. Via holes may also be formed in the dielectric layer 114c at locations where the metal vias 124b will be formed. The via holes may be formed by laser drilling or other suitable process (e.g., etching). A layer of metal material may then be deposited (e.g., by electroplating, CVD or other suitable method) on the etched surface of the dielectric layer 116c and in the via holes to form the metal layers 124a and the metal vias 124b, respectively. Planarization by chemical mechanical polishing (CMP) or other suitable method may then be performed to remove excess metal material on the surface of the dielectric layer 114c. The upper bonding pads 191 may be formed together with the uppermost metal via 124b in the process of forming the upper build-up portion 114. The forming of the upper bonding pads 191 may complete the formation of the package substrate 110.

The package substrate 110 may then be detached from the third carrier substrate 3 by a method similar to the method used to detach the intermediate structure from the first carrier substrate 1 and from the second carrier substrate 2. After the package substrate 110 is detached from the third carrier substrate 3, the BGA 180 (see FIG. 1A) may be formed on the lower bonding pads 192. The BGA 180 may alternatively be formed after the forming of the lower bonding pads 192 (see FIG. 2I) and before detaching the intermediate structure from the second carrier substrate 2. The solder balls 181 of the BGA 180 may be formed, for example, by an electroplating process.

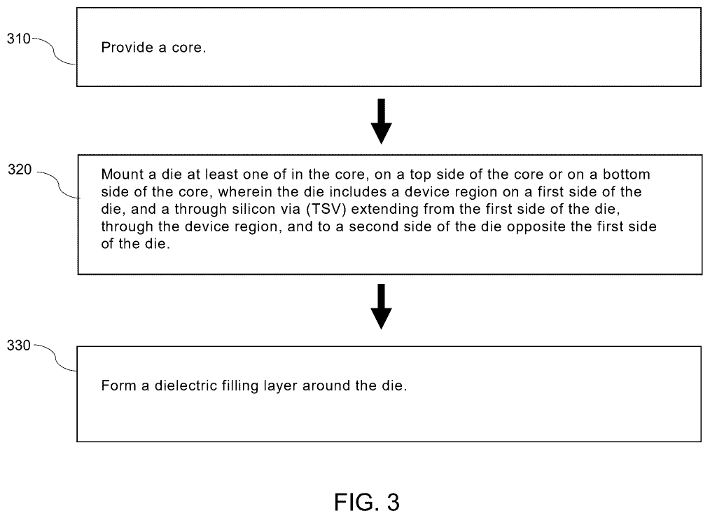

FIG. 3 is a flow chart illustrating a method of making a package substrate 110 according to one or more embodiments. Step 310 includes providing a core 112. Step 320 includes mounting a die 200 at least one of in the core 112, on a top side of the core 112 or on a bottom side of the core 112, wherein the die 200 includes a device region on a first side of the die 200, and a through silicon via (TSV) 203 extending from the first side of the die 200, through the device region, and to a second side of the die 200 opposite the first side of the die. Step 330 includes forming a dielectric filling layer 115 around the die 200.

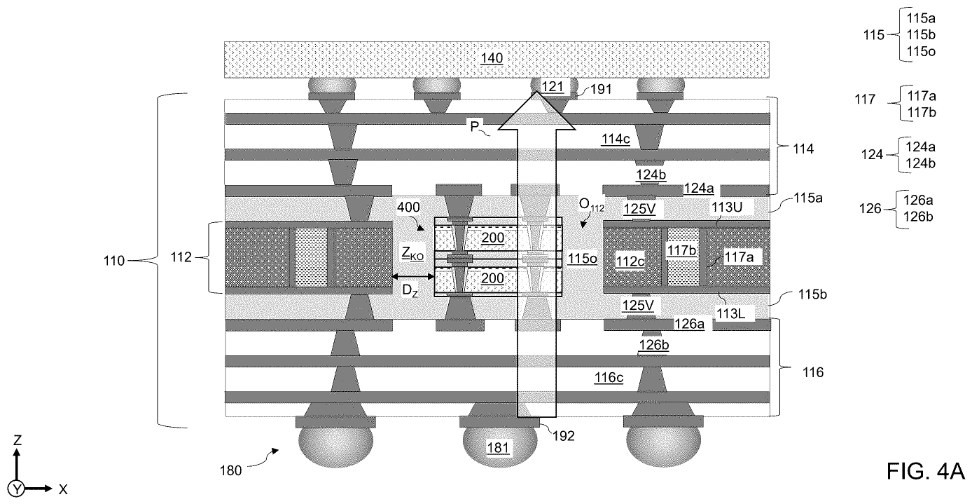

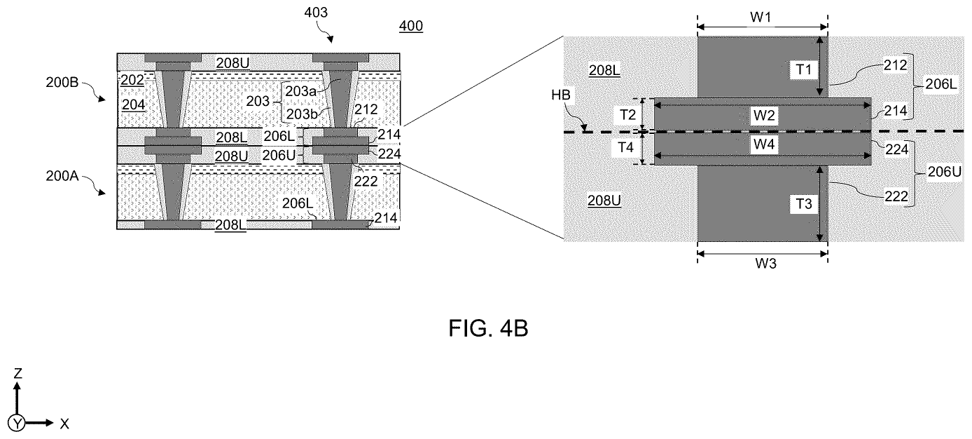

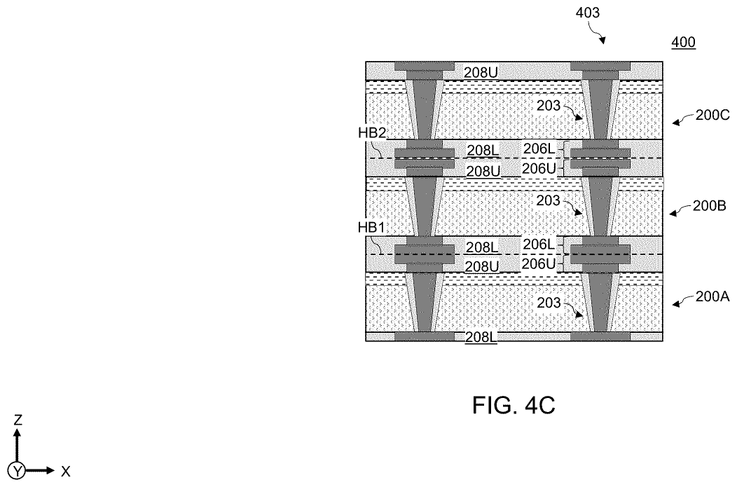

FIG. 4A is a vertical cross-sectional view of the package substrate 110 having a first alternative configuration according to one or more embodiments. As illustrated in FIG. 4A, the package substrate 110 having the first alternative configuration may be substantially the same as the package substrate 110 in FIG. 1A. However, unlike the package substrate 110 in FIG. 1A that may include a die 200 (e.g., a single die) in the core 112, the package substrate 110 in the first alternative configuration may include a plurality of the dies 200 in the form of a die stack 400 in the core 112. The die stack 400 may be located in the core opening O₁₁₂ such that the keep-out zone Z_{KO} having a width D_{Z} (e.g., in a range from 20 μm to 50 μm) may be formed around the periphery of the die stack 400.

As illustrated in FIG. 4A, a thickness the die stack 400 may be substantially the same as a thickness of the core 112. The first alternative configuration of the package substrate 110 may include a new power path P including a substantially direct path (e.g., straight-line path) through the die stack 400. The new power path P may help to reduce a need for horizontal fan-out paths in the package substrate 110.

FIG. 4B is a vertical cross-sectional view of the die stack 400 in the package substrate 110 having the first alternative configuration according to one or more embodiments. As illustrated in FIG. 4B, the dies 200 in the die stack 400 may be identified as first die 200A and second die 200B for ease of understanding.

The die stack 400 may include a pair of dies 200 including a first die 200A and a second die 200B stacked on the first die 200A. The first die 200A and second die 200B may have substantially the same size and be substantially aligned in the z-direction. The TSVs 203 in the first die 200A and second die 200B may also be substantially aligned in the z-direction and constitute a TSV stack 403. The TSVs 203 in the TSV stack 403 may be electrically coupled by the lower bonding pad 206L in the second die 200B and the upper bonding pad 206U in the first die 200A. The TSV stack 403 may serve as part of the new power path P in the package substrate 110 having the first alternative configuration.

Each of the first die 200A and the second die 200B may include an upper dielectric bonding layer 208U and a lower dielectric bonding layer 208L. Each of the upper dielectric bonding layer 208U and a lower dielectric bonding layer 208L may include silicon dioxide, silicon nitride, polyimide or other suitable dielectric materials.

As illustrated in FIG. 4B, the lower bonding pad 206L may be formed in the lower dielectric bonding layer 208L. The lower bonding pad 206L may include a bond pad via 212 contacting the TSV 203, and a bond pad metal 214 on the bond pad via 212. The lower surface of the bond pad metal 214 may be substantially co-planar with the lower surface of the lower dielectric bonding layer 208L. The bond pad via 212 and the bond pad metal 214 may be formed of the same or different materials. It should be noted that the lower bonding pad 206L in the first die 200A (e.g., the lowest die 200 in the die stack 400) may omit the bond pad via 212 so that the bond pad metal 214 may contact (e.g., directly contact) the TSV 203.

The upper bonding pad 206U may be formed in the upper dielectric bonding layer 208U. The upper bonding pad 206U may include a bond pad via 222 contacting the TSV 203 and a bond pad metal 224 on the bond pad via 222. The upper surface of the bond pad metal 224 may be substantially co-planar with the upper surface of the upper dielectric bonding layer 208U. The bond pad via 222 and the bond pad metal 224 may be formed of the same or different materials.

The first die 200A and the second die 200B may be bonded together by a hybrid bond HB (e.g., wafer-on-wafer bond). The lower surface of the lower dielectric bonding layer 208L in the second die 200B may be bonded to the upper surface of the upper dielectric bonding layer 208L in the first die 200A. The bond between the lower dielectric bonding layer 208L in the second die 200B and the upper surface of the upper dielectric bonding layer 208L in the first die 200A may constitute a dielectric-dielectric bond in the hybrid bond HB. The lower surface of the bond pad metal 214 in the second die 200B may be bonded to the upper surface of the bond pad metal 224 in the first die 200A. The bond between the bond pad metal 214 in the second die 200B and the bond pad metal 224 in the first die 200A may constitute a metal-metal bond in the hybrid bond HB.

The hybrid bond HB may have a thickness substantially equal to a combined thickness of the lower dielectric bonding layer 208L in the second die 200B and the upper dielectric bonding layer 208L in the first die 200A. In at least one embodiment, a thickness of each of the lower dielectric bonding layer 208L and the upper dielectric bonding layer 208L may be less than about 2.5 μm. In at least one embodiment, the hybrid bond HB may have a thickness less than about 5 μm.

The hybrid bond HB between the first die 200A and the second die 200B may be formed in a hybrid bonding process. The hybrid bonding process may include, for example, a surface preparation step in which the surfaces of the lower dielectric bonding layer 208L and bond pad metal 214 in the second die 200B and the upper dielectric bonding layer 208L and bond pad metal 224 in the first die 200A are prepared by cleaning and removing any contaminants or oxides that could interfere with bonding. The surface preparation step may help to achieve optimal bonding quality. An alignment step may be performed in which the first die 200A and second die 200B are more precisely aligned to help ensure accurate positioning of the interconnects. The alignment step may be performed, for example, using alignment marks or an optical alignment system. Once aligned, the second die 200B may be positioned on the first die 200A so that the lower dielectric bonding layer 208L in the second die 200B contacts the upper dielectric bonding layer 208L in the first die 200A, and the bond pad metal 214 in the second die 200B contacts the bond pad metal 224 in the first die 200A.

The bonding process may be performed at room temperature (room-temperature bonding) or at elevated temperatures (thermal bonding) depending on the specific bonding technique used. In the bonding process, the lower dielectric bonding layer 208L of the second die 200B and the upper dielectric bonding layer 208U of the first die 200A may be activated to form a chemical bond (e.g., oxide-oxide bond) at the atomic level. In at least one embodiment, dielectric layers (e.g., oxide layers) in the lower dielectric bonding layer 208L and the upper dielectric bonding layer 208U may be brought into contact, allowing oxygen atoms to migrate therebetween and form covalent bonds. In at least one embodiment, elevated temperature and pressure may be applied to form the dielectric-dielectric bond (e.g., oxide-oxide bond). Concurrently with the formation of the dielectric-dielectric bond, a metal-metal bond may be formed between the metal layers of the bond pad metal 214 of the second die 200B and the bond pad metal 224 of the first die 200A. In at least one embodiment, elevated temperature and pressure may be applied to form the metal-metal bond through diffusion or solid-state reactions.

In at least one embodiment, the size and shape of the lower bonding pad 206L may be substantially the same as the size and shape of the upper bonding pad 206U. The bond pad via 212 may have a width W1 (e.g., diameter) in a range from 1.5 μm to 2.0 μm (e.g., about 1.8 μm) and a thickness T1 in a range from 3.0 μm to 5.0 μm (e.g., about 4.0 μm). The bond pad metal 214 may have a width W2 (e.g., diameter) in a range from 2.0 μm to 3.0 μm (e.g., about 2.5 μm) and a thickness T1 in a range from 0.5 μm to 1.0 μm (e.g., about 0.8 μm). The bond pad via 222 may have a width W3 (e.g., diameter) in a range from 1.5 μm to 2.0 μm (e.g., about 1.8 μm) and a thickness T3 in a range from 5.0 μm to 7.0 μm (e.g., about 6.0 μm). The bond pad metal 224 may have a width W4 (e.g., diameter) in a range from 2.0 μm to 3.0 μm (e.g., about 2.5 μm) and a thickness T4 in a range from 0.5 μm to 1.0 μm (e.g., about 0.8 μm).

FIG. 4C is a vertical cross-sectional view of the die stack 400 having an alternative configuration according to one or more embodiments. The die stack 400 having the alternative configuration in FIG. 4C may be substantially the same as the die stack 400 in FIG. 4B. However, the die stack 400 of FIG. 4C may have three dies 200 stacked upon each other. The dies 200 in the die stack 400 of FIG. 4C may be identified as first die 200A, second die 200B, third die 200C for ease of understanding. The die stack 400 of FIG. 4C is not limited to three dies 200 but may include any number dies 200. The TSV stack 403 in the die stack 400 of FIG. 4C may include three TSVs 203 which may be substantially aligned in the z-direction. The die stack 400 of FIG. 4C may include a first hybrid bond HB1 between the first die 200A and second die 200B, and a second hybrid bond HB2 between the second die 200B and the third die 200C.

In the package substrate 110 having the first alternative configuration, the thickness and/or quantity of the dies 200 in the die stack 400 may be adjusted to match the thickness of the core 112. In at least one embodiment, the thickness of the core 112 may be about 1400 μm, a height of each die 200 in the die stack 400 may be in a range from 50 μm to 650 μm. Multiple dies may be used in the die stack 400 to reach total die stack height of at least 1400 μm or more. The dies 200 in the die stack 400 may include a passive component (e.g., capacitor (e.g., digitally tunable capacitor (DTC), inductor, resistor, etc.) or an active component (e.g., transistor, integrated voltage regulator (IVR), etc.). The dies 200 in the die stack 400 may include the same or different devices (e.g., capacitor plus capacitor, capacitor plus IVR, etc.). Further, the TSV stack 403 in the second alternative configuration may provide a new shorter power path to reduce horizontal fan-out paths, the PI performance may be improved, and embedded die characteristics (e.g., capacitance increase, DTC+IVR, etc.) may be enhanced.

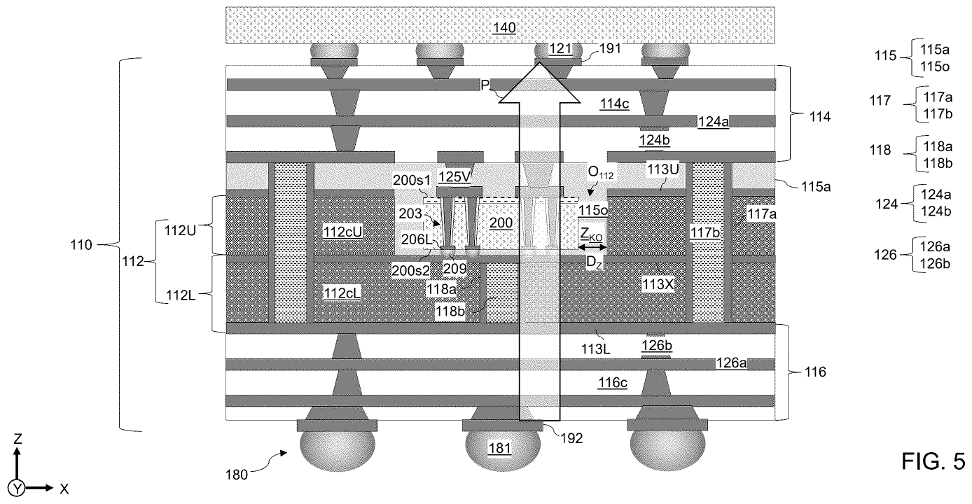

FIG. 5 is a vertical cross-sectional view of a package substrate 110 having a second alternative configuration according to one or more embodiments. As illustrated in FIG. 5, the package substrate 110 having the second alternative configuration may be substantially similar to the package substrate 110 in FIG. 1A. In particular, the package substrate 110 having the second alternative configuration may include a core 112, a core opening O₁₁₂ formed in the core 112, a die 200 mounted in the core opening O₁₁₂, a dielectric filling layer 115 in the core opening O₁₁₂ and on a top side of the core 112, an upper build-up portion 114 on the dielectric filling layer 115 and a lower build-up portion 116 on a bottom side of the core 112. The die 200 may be located in the core opening O₁₁₂ such that the keep-out zone Z_{KO} having a width D_{Z} (e.g., in a range from 20 μm to 50 μm) may be formed around the periphery of the die 200. The die 200 may include a single die or a die stack similar to the die stack 400 (see FIG. 4A).

As with the package substrate 110 in FIG. 1A, the package substrate 110 having the second alternative configuration may include one or more TSVs 203 in the die 200. The TSVs 203 may constitute part of a new power path P including a substantially direct path through the die 200. The new power path P may help to reduce a need for horizontal fan-out paths in the package substrate 110.

However, unlike the package substrate 110 in FIG. 1A, the core 112 in the package substrate 110 having the second alternative configuration may include stacked structure including two or more stacked cores. In at least one embodiment, the core 112 may include a lower core 112L and an upper core 112U stacked on the lower core 112L. Each of the lower core 112L and an upper core 112U may have a structure substantially the same as the core 112 in FIG. 1A. In particular, the lower core 112L and upper core 112U may be substantially symmetrical. In at least embodiment, a thickness of the lower core 112L may be substantially the same as a thickness of the upper core 112U.

The upper core 112U may include the core central portion 112cU (substantially the same as the core central portion 112c) and the upper conductive layer 113U on a top side of the core central portion 112cU. The lower core 112L may include a core central portion 112cL (substantially the same as the core central portion 112c) and an intermediate conductive layer 113X (substantially the same as the upper conductive layer 112cU) on a top side of the core central portion 112cL. The intermediate conductive layer 113X may constitute a metal core separating layer.

The lower core 112L may also include the lower conductive layer 113L on a bottom side of the core central portion 112cL. The core 112 may also include the through vias 117 extending from the lower conductive layer 113L, through both the lower core 112L and the upper core 112U and through the dielectric filling layer upper portion 115a. The core 112 may additionally include a through via 118 in the lower core 112L. The through via 118 may extend from the lower conductive layer 113L to the intermediate conductive layer 113X. The through via 118 may be substantially aligned with the die 200 in the core opening O₁₁₂. The through via 118 may include a metal plating 118a and an inner portion 118b substantially the same as the metal plating 117a and the inner portion 117b of the through vias 117, respectively. In contrast to the package substrate 110 in FIG. 1A where the opening O₁₁₂ may be formed through an entirety of the core 112, in the package substrate 110 having the second alternative configuration, the opening O₁₁₂ (e.g., top-side opening) may be formed in the upper core 112U but not in the lower core 112L. A bottom of the opening O₁₁₂ may be defined by an upper surface of the intermediate conductive layer 113X of the lower core 112L.

The die 200 (e.g., top-side die) may be mounted on the upper surface of the intermediate conductive layer 113X in the opening O₁₁₂. The die 200 may include one or more lower die bonding pads 206L on the second side 200s2 of the die 200. The lower die bonding pads 206L may individually contact each the TSV 203 in the die 200. A solder ball 209 (e.g., microbump) may be formed on each of the lower die bonding pads 206L and connect (e.g., electrically couple) the die 200 to the upper surface of the intermediate conductive layer 113X.

The second alternative configuration of the package substrate 110 with the stacked cores (e.g., lower core 112L and upper core 112U) may enhance the rigidity of the package substrate 100. The lower core 112L and upper core 112U may have a substantially symmetrical design (e.g., substantially the same thicknesses). Further, the through via 118 (e.g., the shorter PTH) may connect the die 200 and the lower build-up portion 116 (e.g., the BGA side of the package substrate 110). In at least one embodiment, the height of a single die 200, the thickness of the upper core 112U and the thickness of the lower core may each be about 650 μm. With the second alternative configuration, the TSV 203 in the die 200 may provide a new shorter power path to reduce horizontal fan-out paths, the PI performance may be improved, and structural rigidity of the package substrate 110 may be retained.

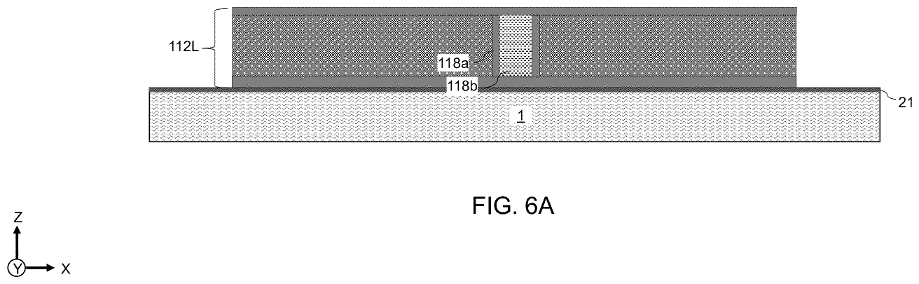

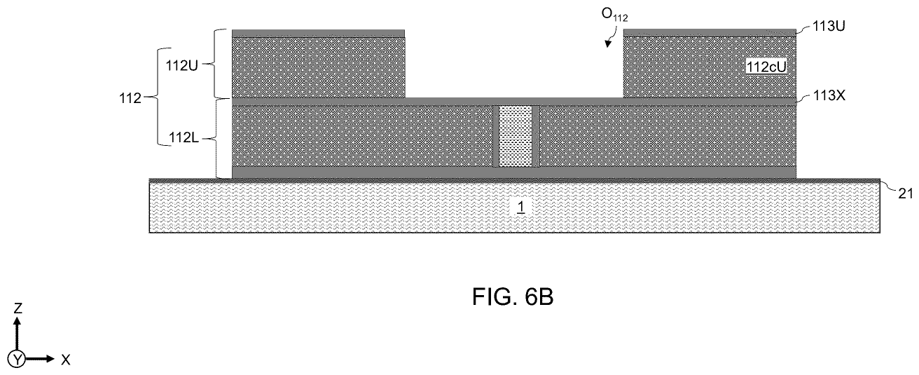

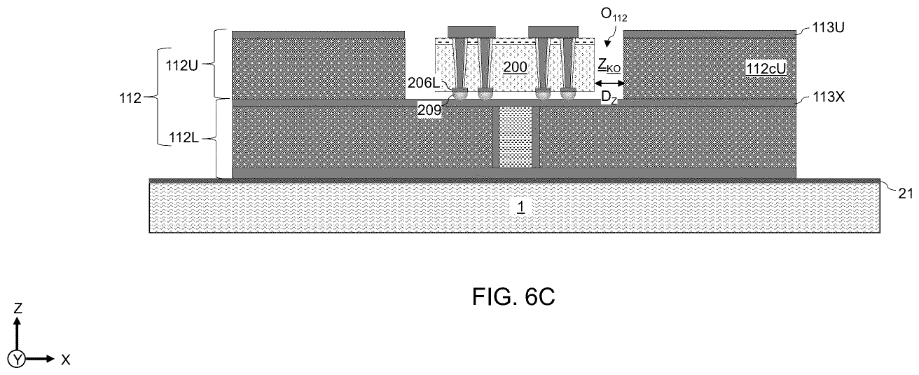

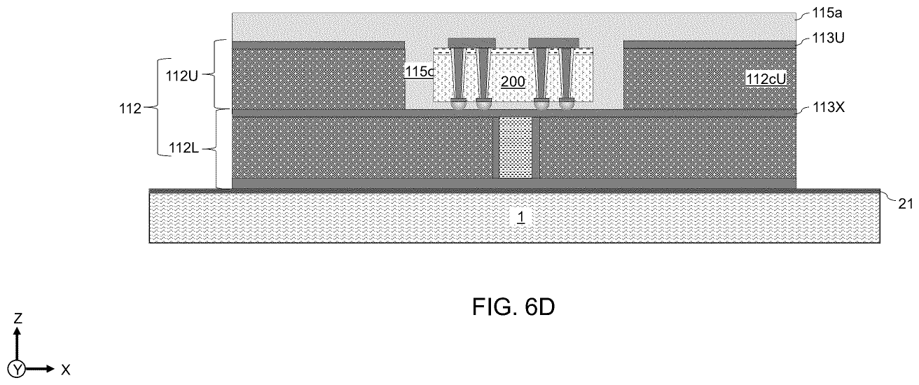

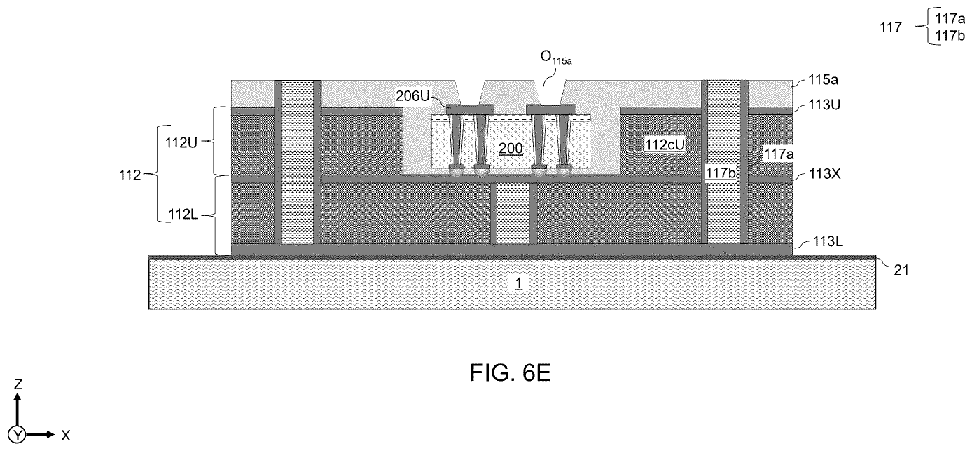

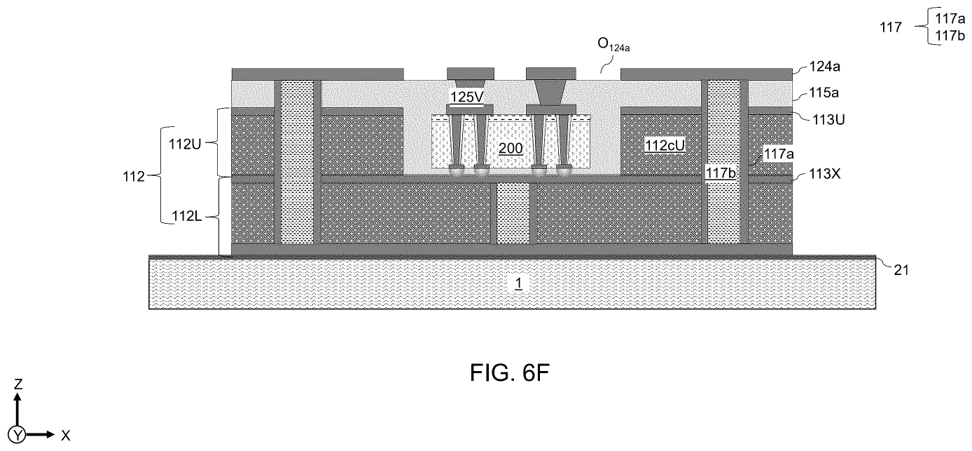

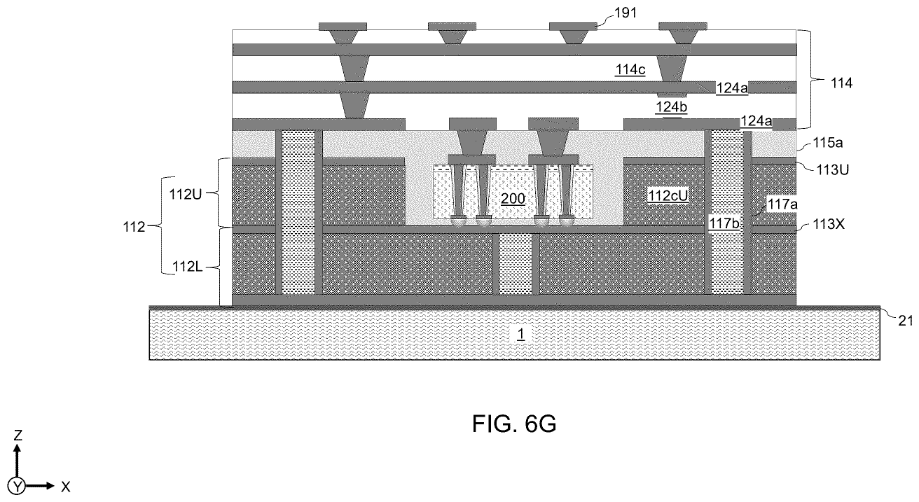

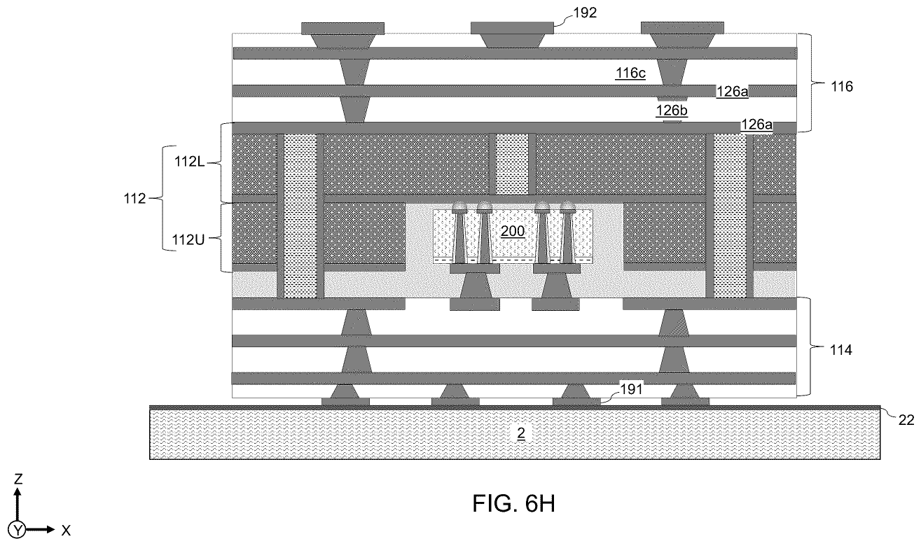

FIGS. 6A-6H are vertical cross-sectional views of intermediate structures in a method of making the package substrate 110 having the second alternative configuration according to one or more embodiments. FIG. 6A is a vertical cross-sectional view of an intermediate structure including the lower core 112L on the first carrier substrate 1 (e.g., carrier wafer) according to one or more embodiments. The lower core 112L may be placed on the first carrier substrate 1 by an electromechanical pick-and-place (PNP) machine. The lower core 112L may be removably attached to the first carrier substrate 1 by the adhesive layer 21 applied to a top surface of the first carrier substrate 1.

FIG. 6B is a vertical cross-sectional view of an intermediate structure including the upper core 112U stacked on the lower core 112L according to one or more embodiments. An adhesive layer (not shown) may be formed on an upper surface of the lower core 112L. The upper core 112U may then be placed on the lower core 112L by an electromechanical pick-and-place (PNP) machine. The upper core 112U may be attached to the first carrier substrate 1 by the adhesive layer.

The core opening O₁₁₂ may be formed in the upper core 112U. The core opening O₁₁₂ may be formed to expose an upper surface of the intermediate conductive layer 113X. The core opening O₁₁₂ may be formed, for example, by a laser drilling process using, for example, an ultraviolet (UV) laser (e.g., excimer laser) or CO₂ laser. The core opening O₁₁₂ may alternatively or additionally be formed by using a photolithographic process.

FIG. 6C is a vertical cross-sectional view of an intermediate structure including the die 200 in the core opening O₁₁₂ according to one or more embodiments. The die 200 may be placed in the core opening O₁₁₂ by an electromechanical pick-and-place (PNP) machine. The die 200 may include, for example, an integrated passive device (IPD). The solder ball 209 (e.g., microbump) on the die 200 may be bonded to the upper surface of the intermediate conductive layer 113X (e.g., metal core separating layer) using a reflow process.

In placing the die 200 in the core opening O₁₁₂, care may be taken to ensure that the center of the die 200 may be aligned with a center of the core opening O₁₁₂. In particular, care may be taken to ensure that the keep-out zone Z_{KO} having a width D_{Z} (e.g., in a range from 20 μm to 50 μm) may be formed around the periphery of the die 200 (e.g., see FIG. 1C).

FIG. 6D is a vertical cross-sectional view of an intermediate structure including the dielectric filling layer 115 on the die 200 according to one or more embodiments. The dielectric filling layer upper portion 115a and dielectric filling layer opening portion 115o may be formed around the die 200 that has been placed in the core opening O₁₁₂.

A layer of dielectric filling material (e.g., ABF) may be deposited on the upper conductive layer 113U of the upper core 112U and in the core opening O₁₁₂. The layer of dielectric filling material may be formed, for example, by at least one of spin-coating, lamination or other suitable methods (e.g., chemical vapor deposition (CVD), physical vapor deposition (PVD), etc.). The layer of dielectric filling material may be formed so as to completely fill the core opening O₁₁₂. The layer of dielectric filling material may be formed so as to be substantially free of air bubbles. The deposited layer of dielectric filling material may (e.g., depending upon the type of dielectric material) be cured by a curing process. The curing process may cross-link the polymers in the dielectric filling material (e.g., resin) and transform it into a hard, durable dielectric layer that may constitute the dielectric filling layer upper portion 115a and the dielectric filling layer opening portion 115o.

FIG. 6E is a vertical cross-sectional view of an intermediate structure including openings O₁₁₅ₐ (e.g., via holes) in the dielectric filling layer upper portion 115a according to one or more embodiments. Openings O₁₁₅ₐ may be formed in the dielectric filling layer upper portion 115a. The openings O₁₁₅ₐ may expose an upper surface of the upper die bonding pads 206U. In at least one embodiment, the openings O₁₁₅ₐ may be formed by a laser drilling process. The laser drilling process may use, for example, an ultraviolet (UV) laser (e.g., excimer laser) or CO2 laser. The openings O₁₁₅ₐ may alternatively or additionally be formed by using a photolithographic process.

Openings (not shown) may also be formed in the dielectric filling layer upper portion 115a for the formation of the through vias 117 (e.g., plated through vias). The openings may extend through the dielectric filling layer upper portion 115a, the upper core 112U and the core central portion 112cL of the lower core 112L. The openings may be formed so as to expose an upper surface of the lower conductive layer 113L of the lower core 112L. The openings may also be formed by a laser drilling process. The openings O₁₁₅ₐ may alternatively or additionally be formed by using a photolithographic process.

Through vias 117 may be formed in the openings that are formed in the dielectric filling layer upper portion 115a. A layer of metal material may be deposited on the wall of the opening by CVD, PVD or other suitable method to form the metal plating 117a on the walls of the openings. Another layer of metal material may be deposited in the opening over the metal plating 117a by CVD, PVD or other suitable method to form the inner portion 117b on the metal plating 117a. After the metal plating 117a and inner portion 117b are formed in the openings, a planarization process such as chemical mechanical polishing (CMP) may be performed to remove excess metal material and make an upper surface of the through vias 117 substantially co-planar with an upper surface of the dielectric filling material upper portion 115a.

FIG. 6F is a vertical cross-sectional view of an intermediate structure including the metal vias 125V in the dielectric filling layer upper portion 115a according to one or more embodiments. The metal vias 125V may be formed in the openings O₁₁₅ₐ. A metal layer 124a of the metal interconnect 124 may also be formed on the surface of the dielectric filling layer upper portion 115a in the same process used to form the metal vias 125V. In particular, the metal layer 124a and the metal vias 125V may be integrally formed as a unit. The metal layer 124a and the metal vias 125V may be formed, for example, by an electroplating process. Other suitable processes may be used to form the metal layer 124a and the metal vias 125V. After the metal layer 126a and the metal vias 125V are formed, the metal layer 124a may be patterned to form the openings O₁₂₄ₐ in the metal layer 126a. The metal layer 126a may be patterned (forming the openings O₁₂₄ₐ) by using a photolithographic process.

FIG. 6G is a vertical cross-sectional view of an intermediate structure including the upper build-up portion 114 according to one or more embodiments. After the metal layer 124a on the dielectric filling layer upper portion 115a has been patterned, the upper build-up portion 114 may be formed on the core 112. The upper build-up portion 114 may be formed by a process that includes alternatingly depositing the dielectric layers 114c (e.g., a build-up film such as ABF) and forming the metal interconnect structure 124 (e.g., metal layers 124a and metal vias 124b) in and on the dielectric layers 114c.

The process may begin with the forming of a dielectric layer 114c by spin-coating, lamination or other suitable process (e.g., CVD, PVD, etc.). A photolithographic process may then be used to pattern the dielectric layer 114c to define the locations where the metal layers 124a will be formed. Via holes may also be formed in the dielectric layer 114c at locations where the metal vias 124b will be formed. The via holes may be formed by laser drilling (using a UV laser for fine via holes or a CO₂laser for larger via holes) or other suitable process (e.g., etching). A layer of metal material may then be deposited (e.g., by electroplating, CVD or other suitable method) on the etched surface of the dielectric layer 114c and in the via holes to form the metal layers 124a and the metal vias 124b, respectively. Planarization by chemical mechanical polishing (CMP) or other suitable method may then be performed to remove excess metal material on the surface of the dielectric layer 114c. The upper bonding pads 191 may be formed together with the uppermost metal via 124b in the process of forming the upper build-up portion 114.

FIG. 6H is a vertical cross-sectional view of an intermediate structure including the lower build-up portion 116 according to one or more embodiments. After the upper bonding pads 191 are formed, the second carrier substrate 2 may be placed on the upper bonding pads 191. The second carrier substrate 2 may include the adhesive layer 22 similar to the adhesive layer 21 on the first carrier substrate 1. The upper bonding pads 191 may be removably attached to the second carrier substrate 2 by the adhesive layer 22.

The intermediate structure may then be inverted (e.g., rotated, flipped) and placed on a stable surface. The intermediate structure may then be detached from the first carrier substrate 1 by deactivating the adhesive layer 21 (e.g., by thermal anneal or ultraviolet light). After the first carrier substrate 1 is detached from the intermediate structure, the lower build-up portion 116 may be formed on the core 112. The lower build-up portion 116 may be formed by a process similar to the process used to form the upper build-up portion 114 (see FIG. 6G). The forming of the lower bonding pads 192 may complete the formation of the package substrate 110.

The package substrate 110 may then be detached from the second carrier substrate 2 by a method similar to the method used to detach the intermediate structure from the first carrier substrate 1. After the package substrate 110 is detached from the second carrier substrate 2, the BGA 180 (see FIG. 1A) may be formed on the lower bonding pads 192. The solder balls 181 of the BGA 180 may be formed, for example, by an electroplating process.

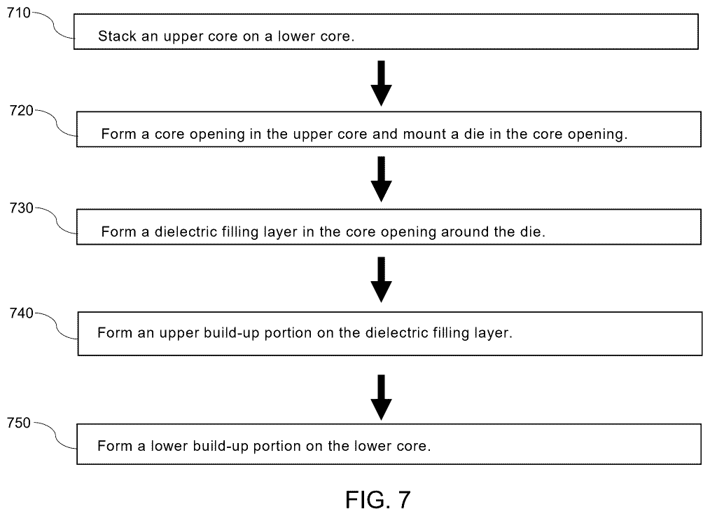

FIG. 7 is a flow chart illustrating a method of making a package substrate 110 according to one or more embodiments. Step 710 includes stacking an upper core 112U on a lower core 112L. Step 720 includes forming a core opening O₁₁₂ in the upper core 112U and mounting a die 200 in the core opening O₁₁₂. Step 730 includes forming a dielectric filling layer 115 in the core opening O₁₁₂ around the die 200. Step 740 includes forming an upper build-up portion 114 on the dielectric filling layer 115. Step 750 includes forming a lower build-up portion 116 on the lower core 112.

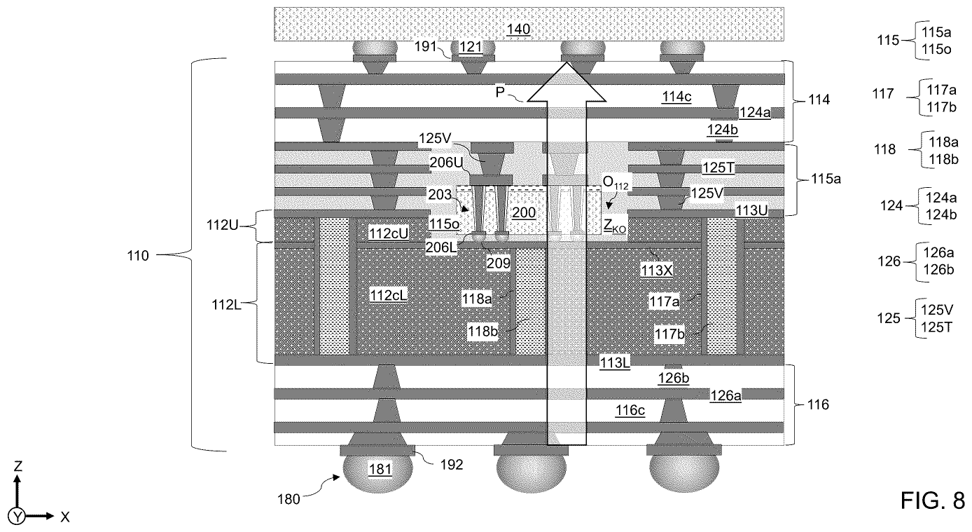

FIG. 8 is a vertical cross-sectional view of a package substrate 110 having a third alternative configuration according to one or more embodiments. As illustrated in FIG. 8, the package substrate 110 having the third alternative configuration may be substantially similar to the package substrate 110 having the second alternative configuration in FIG. 5. In particular, the package substrate 110 having the third alternative configuration may include a core 112 (e.g., stacked core) including a lower core 112L and an upper core 112U stacked on the lower core 112L. The package substrate 110 having the third alternative configuration may also include a core opening O₁₁₂ formed in the upper core 112U, a die 200 mounted on the lower core 112L in the core opening O₁₁₂, a dielectric filling layer 115 in the core opening O₁₁₂ and on a top side of the core 112, an upper build-up portion 114 on the dielectric filling layer 115 and a lower build-up portion 116 on a bottom side of the core 112. The die 200 may be located in the core opening O₁₁₂ such that the keep-out zone Z_{KO} having a width D_{Z} (e.g., in a range from 20 μm to 50 μm) may be formed around the periphery of the die 200. The die 200 may include a single die or a die stack similar to the die stack 400 (see FIG. 4A).

As with the package substrate 110 in FIG. 5, the package substrate 110 having the third alternative configuration may include one or more TSVs 203 in the die 200. The TSVs 203 may constitute part of a new power path P including a substantially direct path through the die 200. The new power path P may help to reduce a need for horizontal fan-out paths in the package substrate 110.

However, unlike the package substrate 110 in FIG. 5, the lower core 112L and an upper core 112U in the package substrate 110 having the third alternative configuration may be asymmetrical (e.g., different thicknesses, different locations of through vias, etc.). In particular, a thickness of the lower core 112L may be different than a thickness of the upper core 112U. In at least one embodiment, the thickness of the lower core 112L may be greater than the thickness of the upper core 112U. In at least one embodiment, the thickness of the lower core 112L may be at least twice the thickness of the upper core 112U.

The thickness of the die 200 (including the upper die bonding pad 206U and the lower die bonding pad 206L) may also be greater than the thickness of the upper core 112U. In at least one embodiment, the thickness of the die 200 may be at least 30% greater than the thickness of the upper core 112U. As a result, the die 200 may extend out of the opening O₁₁₂ and into the dielectric filling layer upper portion 115a. Thus, in order to surround the die 200, the thickness of the dielectric filling layer upper portion 115a in the package substrate 110 having the third alternative configuration in FIG. 8 may be greater than the dielectric filling layer upper portion 115a in FIG. 5. The die 200 may extend out of the opening O₁₁₂ and into the dielectric filling layer upper portion 115a.

The dielectric filling layer upper portion 115a may include a plurality of dielectric layers. A metal interconnect structure 125 may be formed in the dielectric layers of the dielectric filling layer upper portion 115a. The metal interconnect structure 125 may include metal layers 125T (e.g., copper traces) and metal vias 125V connecting the metal layers 125T. The metal layers 125T may be alternatingly formed with the plurality of dielectric layers. The metal vias 125V of the metal interconnect structure 125 may contact and be electrically coupled to the upper die bonding pad 206U of the die 200 and the upper conductive layer 113U on the upper core 112U.

The package substrate 110 having the third alternative configuration in FIG. 8 may include a single embedded die (or a die stack) in a core stack including two more asymmetrical cores (e.g., two or more stacked cores having one or more different features). The stacking of cores may help to increase rigidity of the package substrate 110. The asymmetrical cores may enable the embedded die 200 to be closer to the top die 140, thereby reducing a length of the power path P through the die 200 to the top die 140. The height of the die 200 may be in a range from 50 μm to 650 μm, the upper core thickness may be in a range from 20 μm to 80 μm (e.g., about 50 μm) and the lower core thickness may be in a range from 1200 μm to 1400 μm (e.g., about 1350 μm). A dimension (e.g., lateral dimension) of the embedded die may be in a range from 2 mm×2 mm to 8 mm×8 mm. With the third alternative configuration, the TSVs 203 in the die 200 can provide a new shorter power path to reduce horizontal fan-out paths. Further, the PI performance may be improved and structural rigidity of the package substrate may be retained.

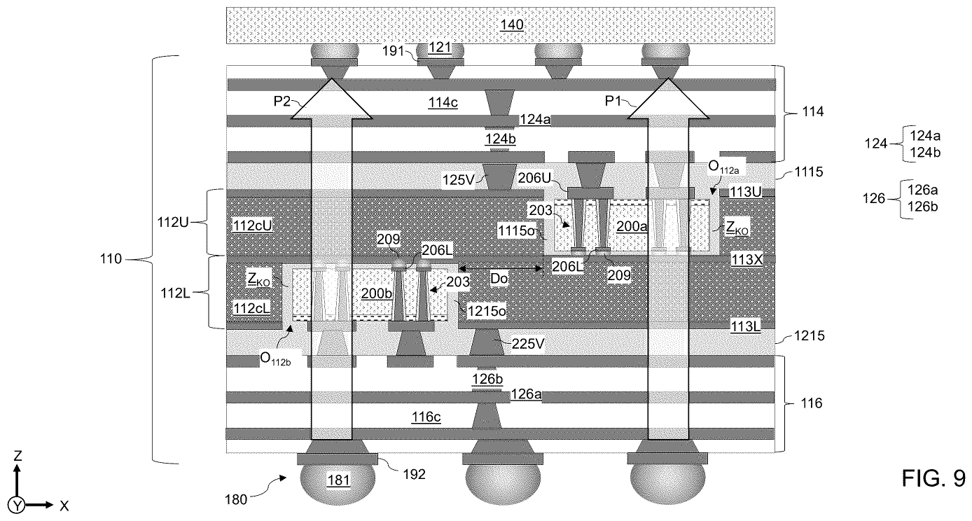

FIG. 9 is a vertical cross-sectional view of a package substrate 110 having a fourth alternative configuration according to one or more embodiments. As illustrated in FIG. 9, the package substrate 110 having the fourth alternative configuration may be substantially similar to the package substrate 110 having the second alternative configuration in FIG. 5. In particular, the package substrate 110 having the fourth alternative configuration may include a core 112 (e.g., stacked core) including a lower core 112L and an upper core 112U stacked on the lower core 112L. The package substrate 110 having the fourth alternative configuration may also include a core opening O₁₁₂ (first opening) formed in the upper core 112U, a die 200a (first die) mounted on the upper core 112U in the core opening O₁₁₂ₐ (first opening), an upper build-up portion 114 on a top side of the core 112 and a lower build-up portion 116 on a bottom side of the core 112.

The die 200a (first die) may be located in the core opening O₁₁₂ₐ (first opening) such that the keep-out zone Z_{KO} having a width D_{Z} (e.g., in a range from 20 μm to 50 μm) may be formed around the periphery of the die 200. The die 200a (first die) may include a single die or a die stack similar to the die stack 400 (see FIG. 4A). The die 200a (first die) may be mounted on the intermediate conductive layer 113X of the lower core 112L. Solder balls 209 (e.g., microbumps) may electrically couple the lower die bonding pads 206L of the die 200a (first die) to the intermediate conductive layer 113X.

However, in contrast to the package substrate 110 in FIG. 5, the package substrate 110 in FIG. 9 may omit the through vias 117 and the through via 118 in the core 112. In addition, the lower core 112L may also include a core opening O_{112b} (second opening). The core opening O_{112b} (second opening) in the lower core 112L may be offset in the x-direction from the core opening O₁₁₂ₐ (first opening) in the upper core 112U by an offset distance Do. In at least one embodiment, the offset distance Do may be at least equal to the lesser of the thickness of the lower core 112L and the thickness of the upper core 112U. In at least one embodiment, the offset distance Do may be in a range from 50 μm to 1000 μm.

Further, a die 200b (second die) may be located in the core opening O_{112b} (second opening) in the lower core 112L. The die 200b (second die) in the lower core 112L may be mounted on a bottom surface of the intermediate conductive layer 113X. Solder balls 209 (e.g., microbumps) may electrically couple the lower die bonding pads 206L of the die 200b (second die) in the lower core 112L to the intermediate conductive layer 113X. The die 200b (second die) in the lower core 112L may be electrically coupled to the die 200a (first die) in the upper core 112U through the intermediate conductive layer 113X.

A functionality of the die 200b (second die) in the lower core 112L may be substantially the same or different than a functionality of the die 200a (first die) in the upper core 112U. As illustrated in FIG. 9, in at least one embodiment, the TSVs 203 of the die 200a (first die) in the upper core 112U may constitute part of a first power path P1 in the package substrate 110, and the TSVs 203 in the die 200b (second die) in the lower core 112L may constitute part of a second power path P2 in the package substrate 110.

As with the die 200a (first die) in the upper core 112U, the die 200b (second die) in the lower core 112L may be located in the core opening O_{112b} (second core opening) such that the keep-out zone Z_{KO} having a width D_{Z} (e.g., in a range from 20 μm to 50 μm) may be formed around the periphery of the die 200b (second die). The die 200b (second die) in the lower core 112L may also include a single die or a die stack similar to the die stack 400 (see FIG. 4A).

The package substrate 100 having the fourth alternative configuration in FIG. 9 may also include a first dielectric filling layer 1115 on the upper core 112U. The first dielectric filling layer 1115 may be located between the upper core 112U and the upper build-up portion 114. The first dielectric filling layer 1115 may include a first dielectric filling layer opening portion 1115o in the core opening O₁₁₂ₐ (first opening) in the upper core 112U.

The package substrate 110 may also include a second dielectric filling layer 1215 on the lower core 112L. The second dielectric filling layer 1215 may be located between the lower core 112L and the lower build-up portion 116. The second dielectric filling layer 1215 may include a second dielectric filling layer opening portion 1215o in the core opening O_{112b} (second opening) in the lower core 112L.

The first dielectric filling layer 1115 and second dielectric filling layer 1215 may be substantially the same as the dielectric filling layer 115 in FIG. 1A. Metal vias 125V may be formed in the first dielectric filling layer 1115. The metal vias 125V may electrically couple the die 200 (first die) to the upper build-up portion 114. The metal vias 125V may also electrically couple the upper conductive layer 113U of the upper core 112U to the upper build-up portion 114.

Metal vias 225V may be formed in the second dielectric filling layer 1215. The metal vias 225V may electrically couple the die 200 (second die) to the lower build-up portion 116. The metal vias 225V may also electrically couple the lower conductive layer 113L of the lower core 112L to the lower build-up portion 116.

With the fourth alternative configuration, the package substrate 110 may increase core area usage. The thickness (e.g., height) of the die 200, thickness of the upper core 112U and thickness of the lower core 112L may each be in a range from 50 μm to 650 μm (e.g., about 650 μm). With this configuration, the TSVs 203 in each of the die 200b (second die) in the lower core 112L and the die 200a (first die) in the upper core 112U may provide a new shorter power path to reduce horizontal fan-out paths. The configuration may also allow for a greater density of embedded components (e.g., embedded dies 200). Further, the PI performance may be improved and structural rigidity of the package substrate may be retained.

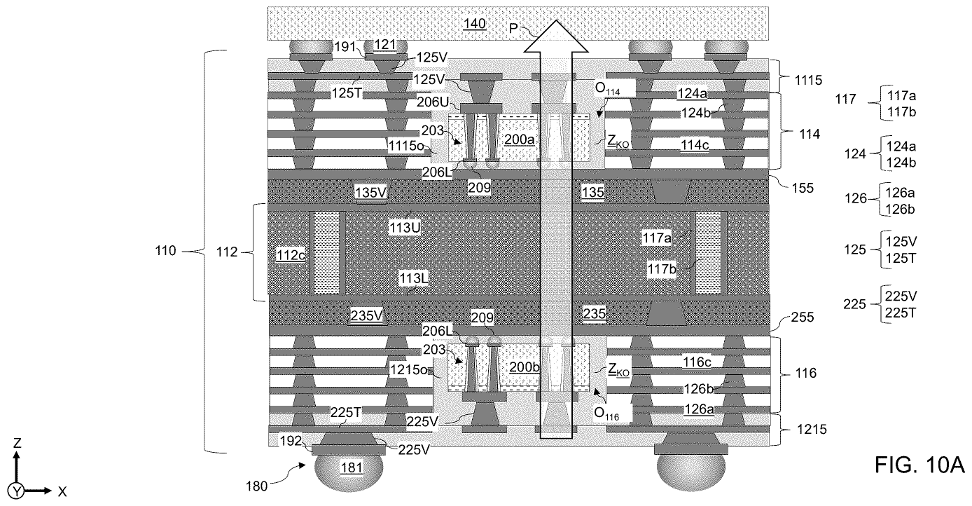

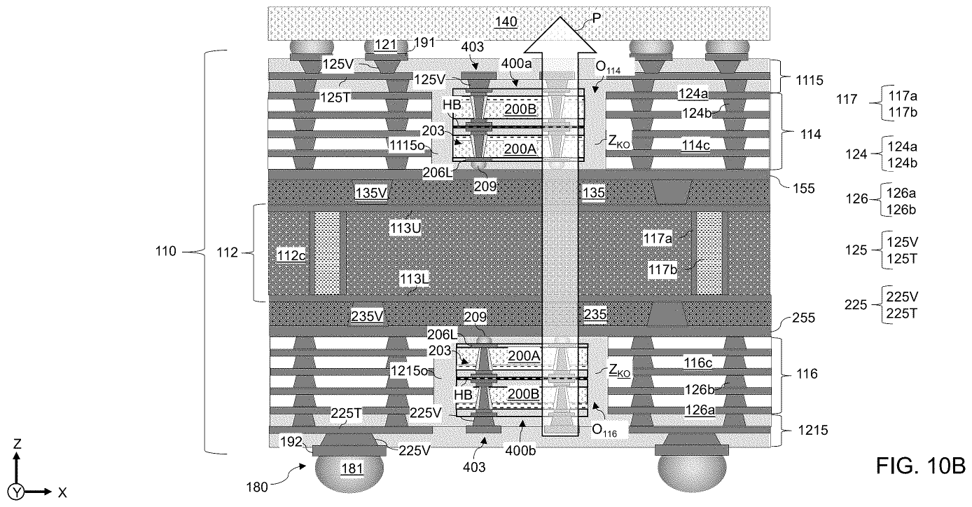

FIG. 10A is a vertical cross-sectional view of a package substrate 110 having a fifth alternative configuration according to one or more embodiments. As illustrated in FIG. 10A, the package substrate 110 having the fifth alternative configuration may be substantially similar to the package substrate 110 in FIG. 9. In particular, the package substrate 110 having the fifth alternative configuration may include a core 112, a die 200a (first die) on a top side of the core 112 and a die 200b (second die) on a bottom side of the core 112. The package substrate 110 may also include an upper build-up portion 114 on a top side of the core 112 and a lower build-up portion 116 on a bottom side of the core 112. The package substrate 110 may also include a first dielectric filling layer 1115 on the top side of the core 112 and a second dielectric filling layer 1215 on the bottom side of the core 112. The die 200a (first die) on the top side of the core 112 may be embedded in the first dielectric filling layer 1115 and the die 200b (second die) on the bottom side of the core 112 may be embedded in the second dielectric filling layer 1215.

However, in contrast to the core 112 in the package substrate 110 in FIG. 9, the core 112 in the package substrate in FIG. 10 may include a single core. The core 112 in FIG. 10 may have a thickness in a range from 1200 μm to 1600 μm (e.g., about 1400 μm). Further, the core 112 may include one or more through vias 117 (e.g., PTH). The through vias 117 may include the metal plating 117a and the inner portion 117b surrounded by the metal plating 117a.

The package substrate 110 having the fifth alternative configuration in FIG. 10A may also include an upper prepreg layer 135 contacting the upper conductive layer 113U on the top side of the core 112. The upper prepreg layer 135 may include a reinforcing fabric of woven or non-woven fibers (e.g., fiberglass) that is pre-impregnated with a resin such as an epoxy resin. A thickness of the upper prepreg layer 135 may be at least 20% of the thickness of the core 112. An upper metal layer 155 may be formed on the upper prepreg layer 135. A metal via 135V may be formed in the upper prepreg layer 135 and electrically couple the upper metal layer 155 to the upper conductive layer 113U on the top side of the core 112.

The package substrate 110 may also include a lower prepreg layer 235 contacting the lower conductive layer 113L on the bottom side of the core 112. The lower prepreg layer 235 may be substantially the same as the upper prepreg layer 135. In particular, the lower prepreg layer 235 may include a reinforcing fabric of woven or non-woven fibers (e.g., fiberglass) that is pre-impregnated with a resin such as an epoxy resin. A thickness of the lower prepreg layer 235 may be at least 20% of the thickness of the core 112. A lower metal layer 255 may be formed on the lower prepreg layer 235. A metal via 235V may be formed in the lower prepreg layer 235 and electrically couple the lower metal layer 255 to the lower conductive layer 113L on the bottom side of the core 112.

As illustrated in FIG. 10A, the upper build-up portion 114 may be formed on the upper metal layer 155. An opening O₁₁₄ may be formed in the upper build-up portion 114. The die 200a (first die) may be mounted on the upper metal layer 155 in the opening O₁₁₄ (first opening). The die 200a (first die) may be located in the opening O₁₁₄ₐ such that the keep-out zone Z_{KO} having a width D_{Z} (e.g., in a range from 20 μm to 50 μm) may be formed around the periphery of the die 200a (first die). The die 200a (first die) may include a single die or a die stack similar to the die stack 400 (see FIG. 4A). Solder balls 209 (e.g., microbumps) may electrically couple the lower die bonding pads 206L of the die 200a (first die) to the upper metal layer 155.

The lower build-up portion 116 may be formed on the lower metal layer 255. An opening O_{116b} may be formed in the lower build-up portion 116. The die 200b (second die) may be mounted on the lower metal layer 255 in the opening O₁₁₆ (second opening). The die 200b (second die) may be located in the opening O₁₁₆ such that the keep-out zone Z_{KO} having a width D_{Z} (e.g., in a range from 20 μm to 50 μm) may be formed around the periphery of the die 200b (second die). The die 200b (second die) may include a single die or a die stack similar to the die stack 400 (see FIG. 4A). Solder balls 209 (e.g., microbumps) may electrically couple the lower die bonding pads 206L of the die 200b to the lower metal layer 255.

A functionality of the die 200a (first die) in the opening O₁₁₄ on the top side of the core 112 may be substantially the same or different than a functionality of the die 200b (second die) in the opening O₁₁₆ on the bottom side of the core 112. As illustrated in FIG. 10A, in at least one embodiment, both the TSVs 203 of the die 200a (first die) in the opening O₁₁₄ and the TSVs 203 of the die 200b (second die) in the opening O_{116b} may constitute part of new power path P in the package substrate 110.

The first dielectric filling layer 1115 may be formed on the upper build-up portion 114 and may include a first dielectric filling layer opening portion 1115o in the opening O₁₁₄ of the upper build-up portion 114. The die 200a (first die) may be embedded in the first dielectric filling layer opening portion 1115o. The first dielectric filling layer 1115 may include a plurality of dielectric layers. A metal interconnect structure 125 may be formed in the dielectric layers of the first dielectric filling layer 1115. The metal interconnect structure 125 may include one or more metal layers 125T (e.g., copper traces) and metal vias 125V connecting the metal layers 125T. The metal layers 125T may be alternatingly formed with the plurality of dielectric layers. The metal vias 125V of the metal interconnect structure 125 may contact and be electrically coupled to the upper die bonding pad 206U of the die 200a (first die) and the upper bonding pad 191 on an upper surface of the first dielectric filling layer 1115.

The second dielectric filling layer 1215 may be formed on the lower build-up portion 116 and may include a second dielectric filling layer opening portion 1215o in the opening O116 of the lower build-up portion 116. The die 200 (second die) may be embedded in the second dielectric filling layer opening portion 1215o. The second dielectric filling layer 1215 may include a plurality of dielectric layers. A metal interconnect structure 225 may be formed in the dielectric layers of the second dielectric filling layer 1215. The metal interconnect structure 225 may include one or more metal layers 225T (e.g., copper traces) and metal vias 225V connecting the metal layers 225T. The metal layers 225T may be alternatingly formed with the plurality of dielectric layers. The metal vias 225V of the metal interconnect structure 225 may contact and be electrically coupled to the upper die bonding pad 206U of the die 200 (second die) and the lower bonding pad 192 on a surface of the second dielectric filling layer 1215.

FIG. 10B is a vertical cross-sectional view of a different version of the package substrate 110 having a fifth alternative configuration according to one or more embodiments. The version of the package substrate 110 having the fifth alternative configuration in FIG. 10B may be substantially the same as the version of the package substrate in FIG. 10A. However, in contrast to the package substrate 110 in FIG. 10A, the version of the package substrate 110 in FIG. 10B includes a die stack 400a (first die stack) in the opening O₁₁₄ on the top side of the core 112 and a die stack 400b (second die stack) in the opening O₁₁₆ on the bottom side of the core 112.

The dies 200 in the die stack 400 may be identified as first die 200A and second die 200B for ease of understanding. The die stack 400 may include a pair of dies 200 including a first die 200A and a second die 200B stacked on the first die 200A. The first die 200A and second die 200B may have substantially the same size and be substantially aligned in the z-direction. The TSVs 203 in the first die 200A and second die 200B may also be substantially aligned in the z-direction and constitute a TSV stack 403. The TSV stack 403 may serve as part of the new power path P in the package substrate 110 having the first alternative configuration. The first die 200A and the second die 200B may be bonded together by a hybrid bond HB (e.g., wafer-on-wafer bond).

With the package substrate 110 having the fifth alternative configuration in FIGS. 10A and 10B, a die 200 or die stack 400 including multiple dies 200 may be embedded in the opening O₁₁₄ in the upper build-up portion 114 of the package substrate 110 and in the opening O₁₁₆ in the lower build-up portion 116 of the package substrate 110. The dies 200 or die stacks 400 may be arranged back-to-back to form a packages substrate 100 having a symmetrical structure. The thickness (height) of the die 200 may be in a range from 50 μm to 200 μm. The thickness of the die stack 400 may be in a range from 100 μm to 400 μm or more depending upon the number of dies 200 in the die stack 400. With this configuration, the TSVs 203 or TSV stacks 403 can provide a new shorter power path. The configuration may also allow for a greater density of embedded components. Further, the PI performance may be improved and structural rigidity of the package substrate may be retained.

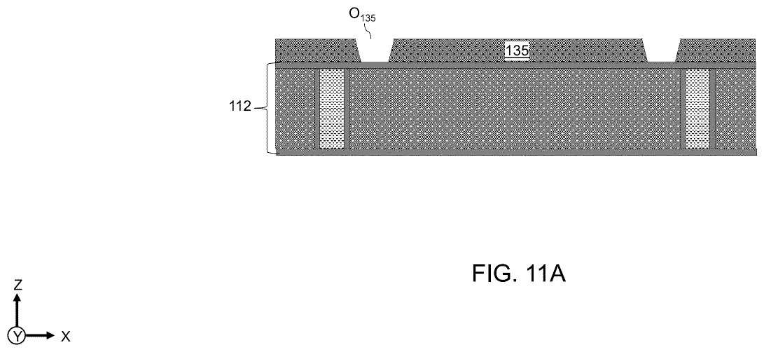

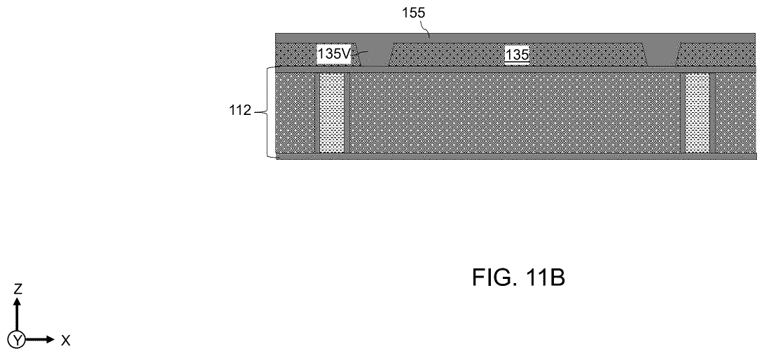

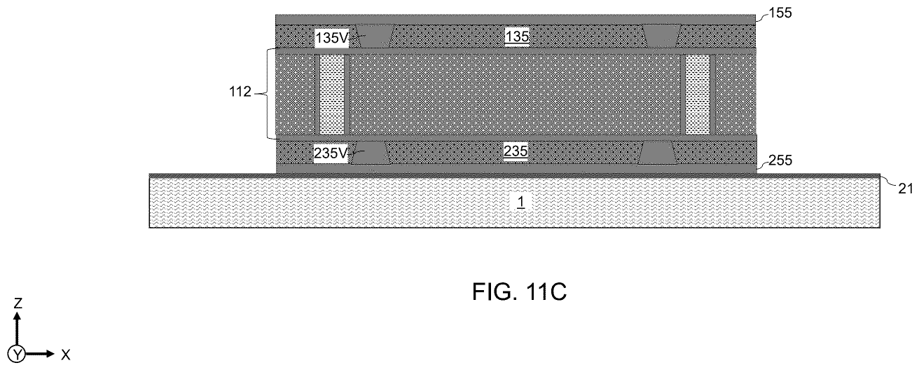

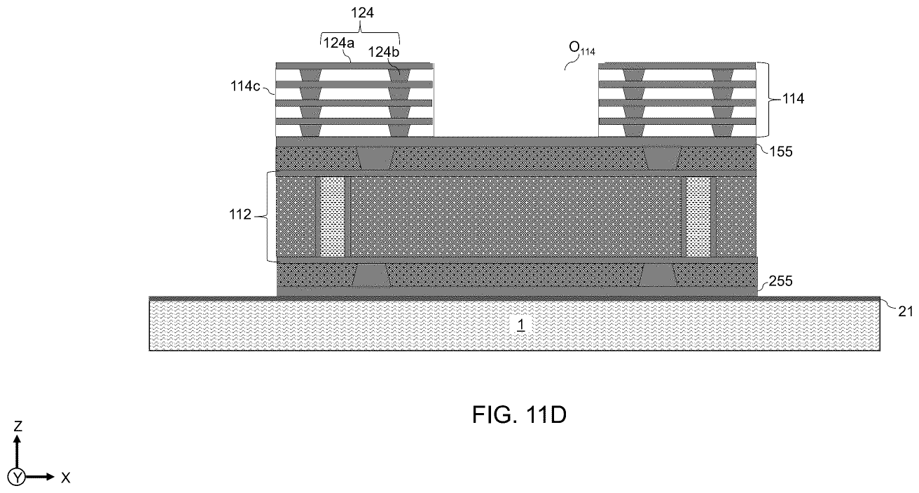

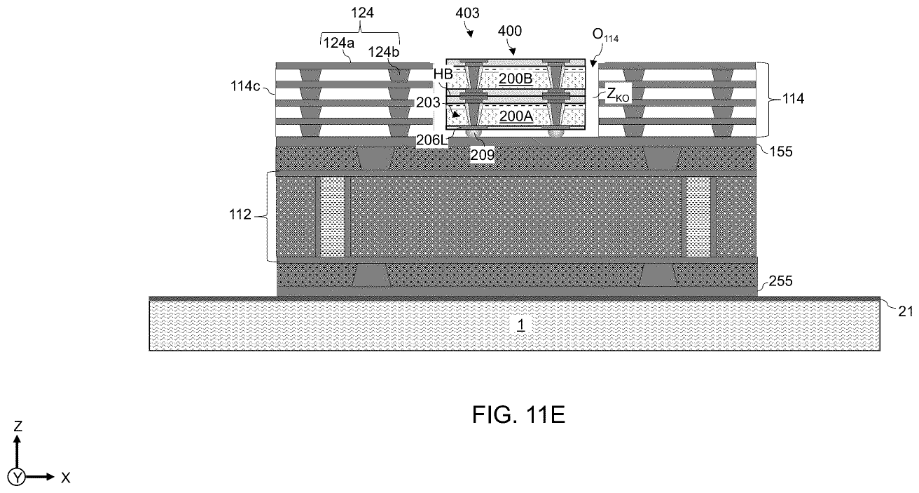

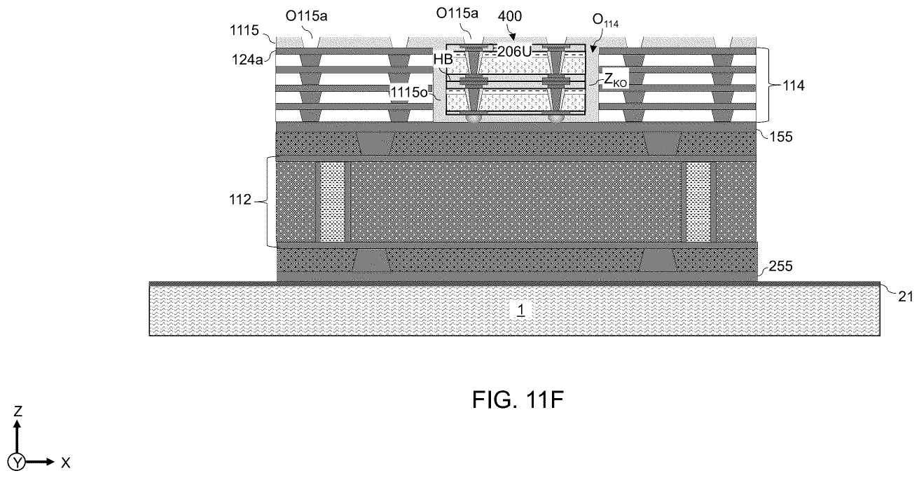

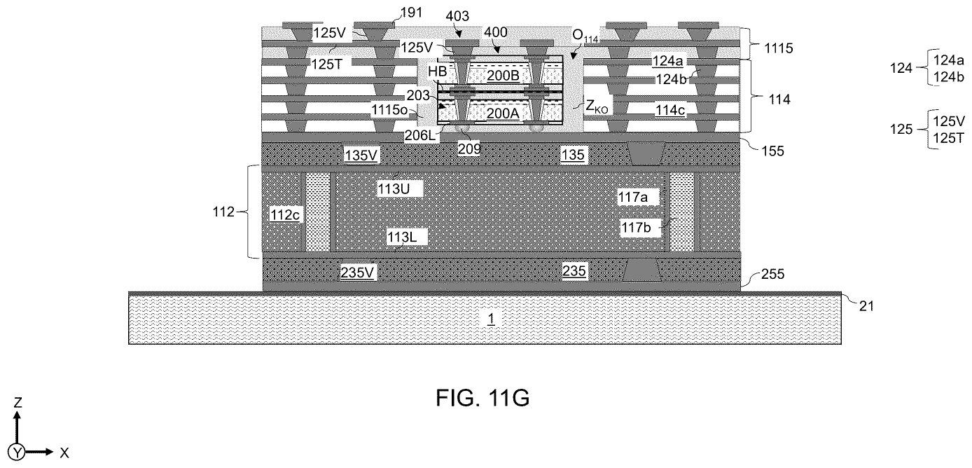

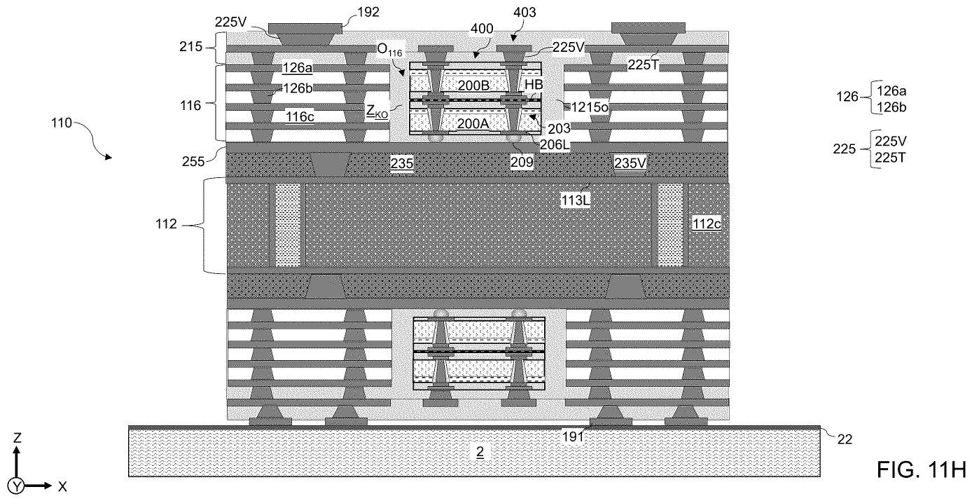

FIGS. 11A-11H are vertical cross-sectional views of intermediate structures in a method of making the package substrate 110 having the fifth alternative configuration according to one or more embodiments. In particular, a method of making the version of the package substrate 110 in FIG. 10B is illustrated in FIGS. 11A-11H.

FIG. 11A is a vertical cross-sectional view of an intermediate structure including the core 112 with the upper prepreg layer 135 according to one or more embodiments. The upper prepreg layer 135 may be formed on the core 112, for example, by a lamination process. In at least one embodiment, the lamination process may include placing a layer of prepreg material on the core 112 and applying heat (e.g., in a range from 170° C. to 200° C.) and pressure (e.g., in a range from 200 psi to 400 psi) for a predetermined time (e.g., in a range from 30 minutes to 90 minutes). The lamination process may bond the layer of prepreg material to the core 112, forming the upper prepreg layer 135. The upper prepreg layer 135 may then be allowed to cool for a period of time.

Upon the upper prepreg layer 135 cooling, openings O₁₃₅ (via holes) may be formed in the upper prepreg layer 135. The openings O₁₃₅ may be formed, for example, by a laser drilling process or by a photolithographic process. Other suitable methods of forming the openings O₁₃₅ are within the contemplated scope of disclosure.

FIG. 11B is a vertical cross-sectional view of an intermediate structure including the metal vias 135V and the upper metal layer 155 on the upper prepreg layer 135 according to one or more embodiments. After the openings O₁₃₅ are formed, a layer of metal material may be deposited on the upper prepreg layer 135 and in the openings O₁₃₅ to form the metal vias 135V in the openings O₁₃₅. The layer of metal material may also be deposited on an upper surface of the upper prepreg layer 135 to form the upper metal layer 155. The layer of metal material may be deposited on the upper prepreg layer 135 by CVD, PVD or other suitable deposition methods.

FIG. 11C is a vertical cross-sectional view of an intermediate structure including the lower prepreg layer 235 according to one or more embodiments. After the upper metal layer 155 is formed on the upper prepreg layer 135, the core 112 may be inverted (e.g., rotated) and the lower prepreg layer 235 may be formed on a bottom side of the core 112. The lower prepreg layer 235 may be formed in a manner similar to the manner of forming the upper prepreg layer 135. In particular, the lower prepreg layer 235 may be formed by a lamination process. Openings (not shown) may be formed in the lower prepreg layer 235 by laser drilling, photolithographic process or other suitable methods. A layer of metal material may then be deposited on the lower prepreg layer 235 to form the metal vias 235V and the lower metal layer 255.

The intermediate structure may then be placed on the first carrier substrate 1 for further processing. The intermediate structure may be placed on the first carrier substrate 1 by an electromechanical pick-and-place (PNP) machine. The lower metal layer 255 may be removably attached to the first carrier substrate 1 by the adhesive layer 21 applied to a top surface of the first carrier substrate 1.

FIG. 11D is a vertical cross-sectional view of an intermediate structure including the upper build-up portion 114 according to one or more embodiments. After the upper prepreg layer 235 and lower prepreg layer are formed on the core 112, the upper build-up portion 114 may be formed on the upper prepreg layer 135.

The upper build-up portion 114 may be formed by a process that includes alternatingly depositing the dielectric layers 114c (e.g., a build-up film such as ABF) and forming the metal interconnect structure 124 (e.g., metal layers 124a and metal vias 124b) in and on the dielectric layers 114c. The process may begin with the forming of a dielectric layer 114c by spin-coating, lamination or other suitable process (e.g., CVD, PVD, etc.). A photolithographic process may then be used to pattern the dielectric layer 114c to define the locations where the metal layers 124a will be formed. Via holes may also be formed in the dielectric layer 114c at locations where the metal vias 124b will be formed. The via holes may be formed by laser drilling (using a UV laser for fine via holes or a CO2 laser for larger via holes) or other suitable process (e.g., etching). A layer of metal material may then be deposited (e.g., by electroplating, CVD or other suitable method) on the etched surface of the dielectric layer 114c and in the via holes to form the metal layers 124a and the metal vias 124b, respectively. Planarization by chemical mechanical polishing (CMP) or other suitable method may then be performed to remove excess metal material on the surface of the dielectric layer 114c.

After the upper build-up portion 114 is formed, the opening O₁₁₄ may be formed in the upper build-up portion 114. The opening O₁₁₄ may be formed, for example, by a photolithographic process or other suitable methods. The opening O₁₁₄ may be formed so as to expose an upper surface of the upper metal layer 155.

FIG. 11E is a vertical cross-sectional view of an intermediate structure including the die stack 400 (first die stack) in the opening O₁₁₄ according to one or more embodiments. The die stack 400 (first die) may be placed in the opening O₁₁₄ by an electromechanical pick-and-place (PNP) machine. The die stack 400 (first die stack) may include, for example, an integrated passive device (IPD). The solder ball 209 (e.g., microbump) on the die stack 400 (first die stack) may be bonded to the upper surface of the upper metal layer 155 using a reflow process.

In placing the die stack 400 (first die stack) in the opening O₁₁₄ (first opening), care may be taken to ensure that the center of the die stack 400 (first die stack) may be aligned with a center of the opening O₁₁₄ (first opening). In particular, care may be taken to ensure that the keep-out zone Z_{KO} having a width D_{Z} (e.g., in a range from 20 μm to 50 μm) may be formed around the periphery of the die stack 400 (first die stack) (e.g., see FIG. 1C).

FIG. 11F is a vertical cross-sectional view of an intermediate structure including the first dielectric filling layer 1115 on the die stack 400 (first die stack) according to one or more embodiments. After the die stack 400 (first die stack) has been placed in the opening O₁₁₄ (first opening), the first dielectric filling layer 1115 including the first dielectric filling layer opening portion 1115o may be formed. The first dielectric filling layer 1115 may be formed by depositing layer of dielectric filling material (e.g., ABF) on the upper build-up layer 114 and in the opening O₁₁₄ (first opening). The layer of dielectric filling material may be formed, for example, by at least one of spin-coating, lamination or other suitable methods (e.g., chemical vapor deposition (CVD), physical vapor deposition (PVD), etc.). After the layer of dielectric filling material is deposited, the layer of dielectric filling material may (e.g., depending upon the type of dielectric material) be cured by a curing process.

After the first dielectric filling layer 1115 is formed, openings O₁₁₅ₐ may be formed in the first dielectric filling layer 1115. The openings O₁₁₅ₐ may expose an upper surface of the upper die bonding pads 206U. The openings O₁₁₅ₐ may also expose an upper surface of an uppermost metal layer 124a in the upper build-up portion 114. In at least one embodiment, the openings O₁₁₅ₐ may be formed by a laser drilling process. The laser drilling process may use, for example, an ultraviolet (UV) laser (e.g., excimer laser) or CO2 laser. The openings O₁₁₅ₐ may alternatively or additionally be formed by using a photolithographic process.

FIG. 11G is a vertical cross-sectional view of an intermediate structure including the metal vias 125V in the first dielectric filling layer 1115 according to one or more embodiments. After the openings O₁₁₅ₐ are formed, the metal vias 125V may be formed in the openings O₁₁₅ₐ. A metal layer 125T may also be formed along with the metal vias 125V. The metal vias 125V and metal layer 125T may be formed by an electroplating process or other suitable methods. Additional layers of dielectric filling material may then be deposited along with metal vias 125V and metal layers 125T in a build-up process similar to the process used to form the upper build-up portion 114. The metal vias 125V and metal layers 125T may constitute the metal interconnect structure 125 in the first dielectric filling layer 1115. The upper bonding pads 191 may be formed together with the uppermost metal via 125V in the process of forming the metal interconnect structure 125.

FIG. 11H is a vertical cross-sectional view of the completed package substrate 110 having the fifth alternative configuration according to one or more embodiments. After the upper bonding pads 191 are formed, the second carrier substrate 2 may be placed on the upper bonding pads 191 of the intermediate structure in FIG. 11G. The second carrier substrate 2 may include the adhesive layer 22 similar to the adhesive layer 21 on the first carrier substrate 1. The upper bonding pads 191 may be removably attached to the second carrier substrate 2 by the adhesive layer 22. The intermediate structure may then be inverted (e.g., rotated) and placed on a stable surface. The intermediate structure may then be detached from the first carrier substrate 1 by deactivating the adhesive layer 21 (e.g., by thermal anneal or ultraviolet light).

After the first carrier substrate 1 is detached from the intermediate structure, the lower build-up portion 116 may be formed on the lower prepreg layer 235. The lower build-up portion 116 may be formed on the lower prepreg layer 235 by a process similar to the process used to form the upper build-up portion 114 (see FIG. 11E). The opening O₁₁₆ may then be formed in lower build-up portion 116 by a photolithographic process or other suitable process. The die stack 400 (second die stack) may then be placed in the opening O₁₁₆ using an electromechanical PNP machine or other suitable method. The second dielectric filling layer 1215 may then be formed on the lower build-up portion 116 and in the opening O₁₁₆ (second opening). The second dielectric filling layer 1215 may be built up in a manner similar to the method used to form the lower build-up portion 116. The build-up process may include the formation of the metal interconnect structure 225 including metal vias 225V and metal layers 225T in the second dielectric filling layer 1215. The lower bonding pads 191 may be formed together with a metal via 225V in the process of forming the metal interconnect structure 225. The formation of the lower bonding pads 191 may complete the formation of the package substrate 110 having the fifth alternative configuration.

The package substrate 110 may then be detached from the second carrier substrate 2 by a method similar to the method used to detach the intermediate structure from the first carrier substrate 1. After the package substrate 110 is detached from the second carrier substrate 2, the BGA 180 (see FIG. 1A) may be formed on the lower bonding pads 192. The solder balls 181 of the BGA 180 may be formed, for example, by an electroplating process.

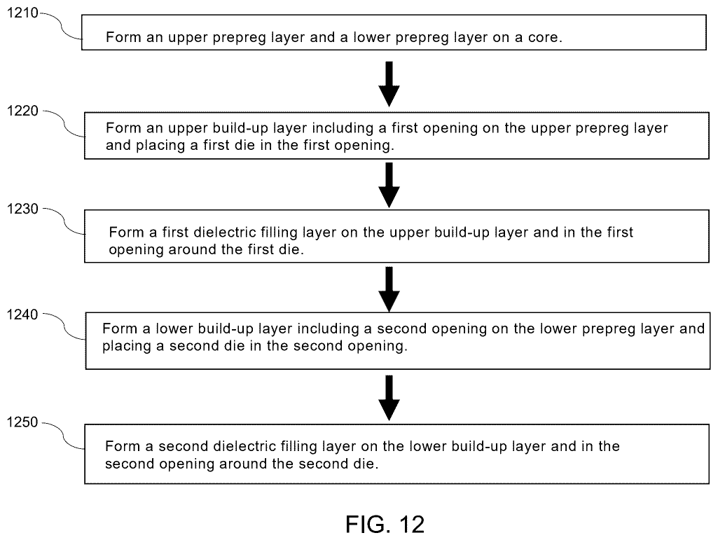

FIG. 12 is a flow chart illustrating a method of making a package substrate 110 according to one or more embodiments. Step 1210 includes forming an upper prepreg layer 135 and a lower prepreg layer 235 on a core 112. Step 1220 includes forming an upper build-up layer 114 including a first opening O₁₁₄ on the upper prepreg layer 135 and placing a first die stack 400 in the first opening O₁₁₄. Step 1230 includes forming a first dielectric filling layer 1115 on the upper build-up layer 114 and in the first opening O₁₁₄ around the first die stack 400. Step 1240 includes forming a lower build-up layer 116 including a second opening O₁₁₆ on the lower prepreg layer 235 and placing a second die stack 400 in the second opening O₁₁₆. Step 1250 includes forming a second dielectric filling layer 1215 on the lower build-up layer 116 and in the second opening O₁₁₆ around the second die stack 400.

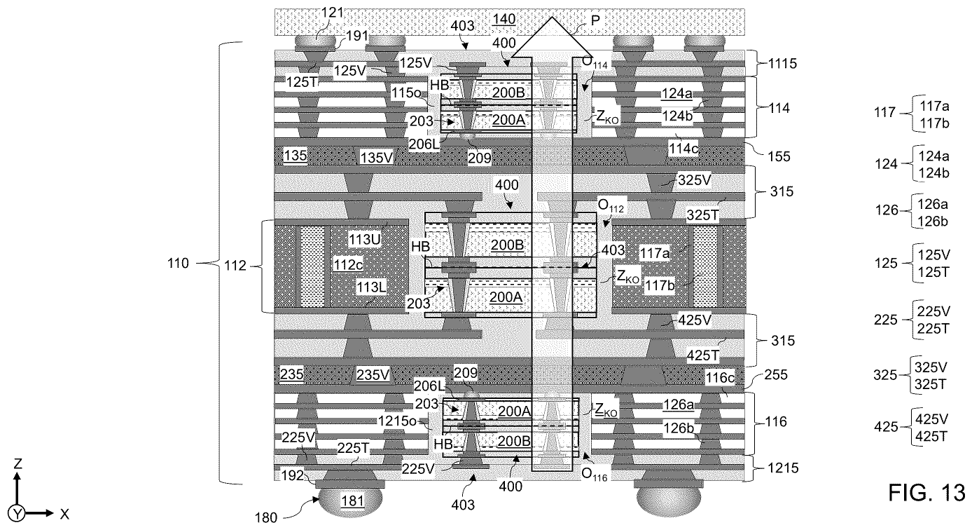

FIG. 13 is a vertical cross-sectional view of a package substrate 110 having a sixth alternative configuration according to one or more embodiments. As illustrated in FIG. 13, the package substrate 110 having the sixth alternative configuration may be substantially similar to the package substrate 110 in FIG. 10B. In particular, the core 112 may include a single core having a thickness in a range from 1200 μm to 1600 μm (e.g., about 1400 μm). The package substrate 100 may include an upper prepreg layer 135 on a top side of the core 112 and a lower prepreg layer 235 on a bottom side of the core 112. The package substrate 110 may also include an upper build-up portion 114 on the upper prepreg layer 135 and a lower build-up portion 116 on the lower prepreg layer 235. The package substrate 110 may also have an opening O₁₁₄ in the upper build-up portion 114 and an opening O₁₁₆ in the lower build-up portion 116. The package substrate 110 may also include a die stack 400 (first die stack) in the opening O₁₁₄ and a die stack 400 (second die stack) in the opening O₁₁₆ (second opening). The package substrate 110 may also include a first dielectric filling layer 1115 on the upper build-up portion 114 and in the opening O₁₁₄ around the die stack 400 (first die stack). The package substrate 110 may also include a second dielectric filling layer 1215 on the lower build-up portion 116 and in the opening O₁₁₆ around the die stack 400 (second die stack).

However, in contrast to the package substrate 110 in FIG. 10B, the package substrate 110 having the sixth alternative configuration in FIG. 13 may include a core opening O₁₁₂ in the core 112. The package substrate 110 may also include a die stack 400 (third die stack) in the core opening O₁₁₂ (third opening). The package substrate 110 may also include a central dielectric filling layer 315 formed on a top side of the core 112 between the core 112 and the upper prepreg layer 135, and on a bottom side of the core 112 between the core 112 and the lower prepreg layer 235. The central dielectric filling layer 315 may also be formed in the core opening 112 around the die stack 400.

A metal interconnect structure 325 may be formed in the central dielectric filling layer 315 on the top side of the core 112 and electrically couple the upper conductive layer 113U of the core 112 to the upper prepreg layer 135. The metal interconnect structure 325 may also be electrically coupled to a top side of the die stack 400 in the core opening O₁₁₂ (third opening). The metal interconnect structure 325 may include metal layers 325T and metal vias 325V connecting the metal layers 325T.

A metal interconnect structure 425 may be formed in the central dielectric filling layer 315 on the bottom side of the core 112 and electrically couple the lower conductive layer 113L of the core 112 to the lower prepreg layer 235. The metal interconnect structure 425 may also be electrically coupled to a bottom side of the die stack 400 in the core opening O₁₁₂ (third opening). The metal interconnect structure 425 may include metal layers 425T and metal vias 425V connecting the metal layers 425T.

The die stack 400 (third die stack) may be located in the core opening O₁₁₂ such that the keep-out zone Z_{KO} having a width D_{Z} (e.g., in a range from 20 μm to 50 μm) may be formed around the periphery of the die stack 400 (third die stack). The die stack 400 (third die stack) in the core opening O₁₁₂ may alternatively include a single die 200 instead of the die stack 400 (third die stack). A single die 200 may have a thickness in a range from 50 μm to 200 μm.

A functionality of the die stack 400 (third die stack) in the core opening O₁₁₂ may be substantially the same or different than the die stack 400 (first die stack) in the opening O₁₁₄ on the top side of the core 112 and may be substantially the same or different than a functionality of the die stack 400 (second die stack) in the opening O₁₁₆ on the bottom side of the core 112. As illustrated in FIG. 13, in at least one embodiment, each of the TSV stack 403 in the die stack 400 (third die stack) in the opening O₁₁₂ (third opening), the TSV stack 403 in the die stack 400 (first die stack) in the opening O₁₁₄ and the TSV stack 403 in the die stack 400 (second die stack) in the opening O₁₁₆ may constitute part of new power path P in the package substrate 110.

With the sixth alternative configuration, the package substrate 110 may include multiple embedded die stacks 400 (or alternatively, dies 200) in the upper build-up portion 114, lower build-up portion 116 and core 112 of the package substrate 110. The die stacks 400 may be arranged back-to-back so as to form the package substrate 110 with a symmetrical structure. Further, the TSV stacks 403 in the die stacks 400 (e.g., the TSVs 203 in the TSV stacks 403) can provide a new shorter power path. The configuration may also allow for a greater density of embedded components, improved PI performance and retention of the structural rigidity of the package substrate 110.

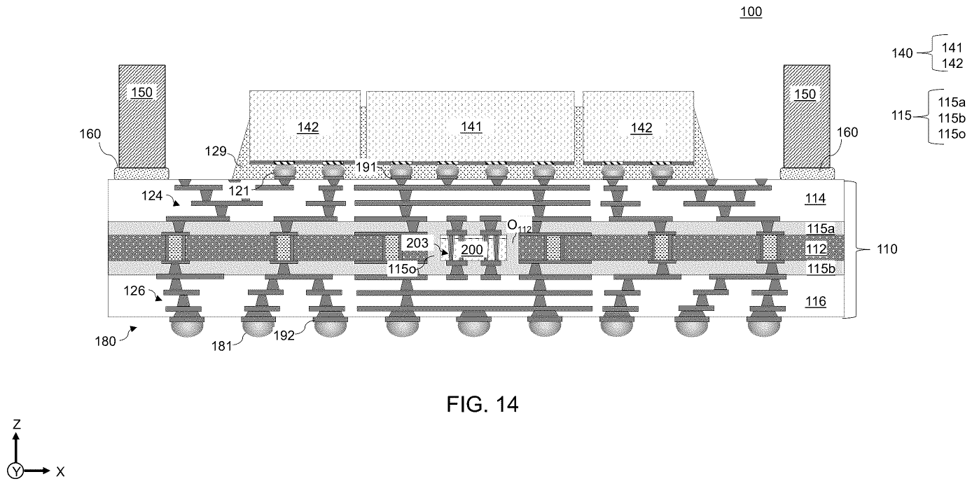

FIG. 14 is a vertical cross-sectional view of a package structure 100 including the package substrate 110 according to one or more embodiments. As illustrated in FIG. 14, the package substrate 110 may have the configuration as illustrated in FIG. 1A. However, any of the various configurations of the package substrate 110 may be used in the package structure 100.

As further illustrated in FIG. 14, the package structure 100 may include top dies 140 mounted on the package substrate 110. The top dies 140 may include a first semiconductor die 141 and second semiconductor dies 142. The package structure 100 may also include solder bumps 121 (e.g., C4 bumps) to connect die bonding pads of the top dies 140 to the upper bonding pads 191 of package substrate 110. A package underfill layer 129 may also be around the top dies 140, between the top dies 140 and the package substrate 110 and around the solder bumps 121. The package structure 100 may also include a stiffener ring 150 around the top dies 140 on the upper surface of the package substrate 110. The stiffener ring 150 may be fixed to the upper surface of the package substrate 110 by an adhesive layer 160.

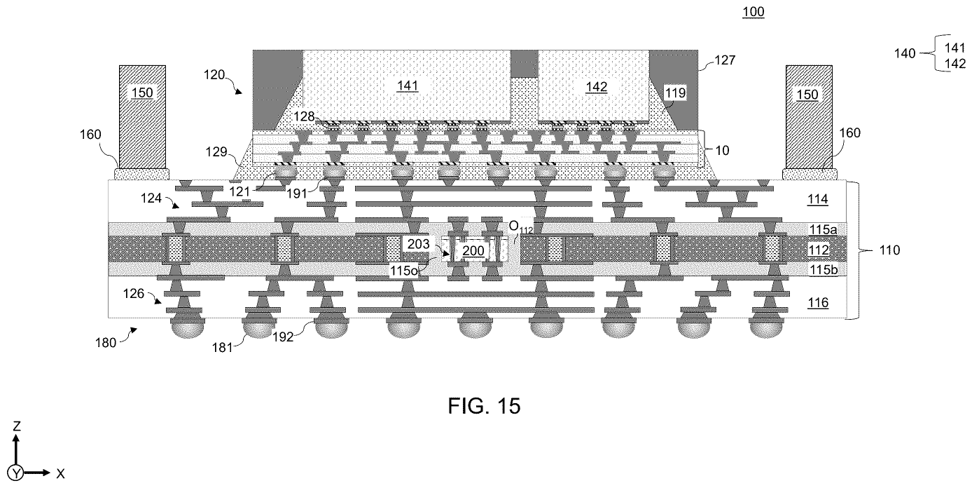

FIG. 15 is a vertical cross-sectional view of a package structure 100 having an alternative configuration according to one or more embodiments. As illustrated in FIG. 15, the package substrate 100 may have the configuration as illustrated in FIG. 1A. However, any of the various configurations of the package substrate 110 may be used in the package structure 100 having the alternative configuration in FIG. 15.

As further illustrated in FIG. 15, the package structure having the alternative configuration may be substantially the same as the package structure in FIG. 14. However, instead of having the top dies 140 mounted on the package substrate 110, the package structure 100 having the alternative configuration may include an interposer module 120 mounted on the package substrate 110. The interposer module 120 may be mounted on the package substrate 110 by a plurality of solder bumps 120 (e.g., C4 bumps). A package underfill layer 129 may be formed on the package substrate 110 around the interposer module 120 and around the solder bumps 121.

The interposer module 120 may include an interposer 10 and top dies 140 mounted on the interposer by microbumps 128. The interposer module 120 may also include a module underfill layer 119 formed on the interposer 10 around the top dies 140. A molding material layer 127 may be formed on the interposer 10 around the module underfill layer 119 and around the top dies 140.

Referring to FIGS. 1A-15, a package substrate 110 may include a core 112, a dielectric filling layer 115, 215, 315 formed at least on the core 112 or in the core 112, and a die 200 in the dielectric filling layer 115, 215, 315, including a device region 202 on a first side 200s1 of the die 200, and a through silicon via (TSV) 203 extending from the first side 200s1 of the die 200, through the device region 202, and to a second side 200s2 of the die 200 opposite the first side 200s1 of the die 200.

In one embodiment, the package substrate 110 may include a power supply path P in a direction from a bottom side of the core 112 to a top side of the core 112, and the TSV 203 may be in the power supply path P of the package substrate 110. In one embodiment, the core 112 may include a core opening O₁₁₂, the dielectric filling layer 115 may be in the core opening O₁₁₂ and the die 200 may be in the core opening O₁₁₂. In one embodiment, the core opening O₁₁₂ may be defined by an inner sidewall of the core 112, and the die 200 may be separated from the inner sidewall of the core 112 by a keep-out zone Z_{KO}. In one embodiment, the core opening O₁₁₂ may extend through an entirety of the core 112 and the dielectric filling layer 115 may include a dielectric filling layer upper portion 115a on a top side of the core 112, and a dielectric filling layer lower portion 115b on a bottom side of the core 112. In one embodiment, the package substrate 110 may further include an upper build-up portion 114 including a metal interconnect structure 124 on the dielectric filling layer upper portion 115b, and a lower build-up portion 116 including a metal interconnect structure 126 on the dielectric filling layer lower portion 115b, wherein the TSV 203 may be electrically coupled to the metal interconnect structure 124 in the upper build-up portion 114 and to the metal interconnect structure 126 in the lower build-up portion 116. In one embodiment, the die 200 may include a plurality of dies in a die stack 400, and the plurality of dies may be bonded together by a hybrid bond HB. In one embodiment, the die stack 400 may include an upper die bonding pad 206U electrically coupled to the metal interconnect structure 124 in the upper build-up portion 114, and a lower die bonding pad 206L electrically coupled to the metal interconnect structure 126 in the lower build-up portion 116, wherein the TSVs 203 in the plurality of dies may be substantially aligned and electrically couple the upper die bonding pad 206U to the lower die bonding pad 206L. In one embodiment, the core 112 may include a plurality of cores 112U, 112L in a core stack, the plurality of cores 112U, 112L includes a lower core 112L and an upper core 112U including a first opening O₁₁₂ stacked on the lower core 112L, and the die 200 may include a first die 200 in the first opening O₁₁₂.

In one embodiment, a thickness of the upper core 112U may be substantially the same as a thickness of the lower core 112L. In one embodiment, a thickness of the upper core 112U may be less than a thickness of the lower core 112L. In one embodiment, the upper core 112U may be separated from the lower core 112L by a metal core separating layer 113X, and the first die 200 may be mounted on the metal core separating layer 113X. In one embodiment, the lower core 112L may include a second opening O₁₁₂, and the die 200 may include a second die 200 in the second opening O₁₁₂ and mounted on the metal core separating layer 113X. In one embodiment, the package substrate 110 may further include an upper prepreg layer 135 on a top side of the core 112, wherein the dielectric filling layer may include a first dielectric filling layer 1115 on the upper prepreg layer 135 and the die 200 may include a first die 200 in the first dielectric filling layer 1115, and a lower prepreg layer 235 on a bottom side of the core 112, wherein the dielectric filling layer may include a second dielectric filling layer 1215 on the lower prepreg layer 235 and the die 200 may include a second die 200 in the second dielectric filling layer 1215. In one embodiment, the first die 200 may include a plurality of dies in a first die stack 400 and bonded together by a hybrid bond HB, and the second die 200 may include a plurality of dies in a second die stack 400 and bonded together by a hybrid bond HB. In one embodiment, the core 112 may include a core opening O₁₁₂, the dielectric filling layer may include a third dielectric filling layer 315 in the core opening O₁₁₂ and between the upper prepreg layer 135 and the lower prepreg layer 235, and the die 200 may include a third die 200 in the core opening O₁₁₂.

Referring again to FIGS. 1A-15, a method of making a package substrate 110 may include providing a core 112, mounting a die 200 on the core 112 or in the core 112, wherein the die 200 may include a device region 202 on a first side 200s1 of the die 200, and a through silicon via (TSV) 203 extending from the first side 200s1 of the die 200, through the device region 202, and to a second side 200s2 of the die 200 opposite the first side 200s1 of the die 200, and forming a dielectric filling layer around the die 200.

In one embodiment, the method may further include forming a core opening O₁₁₂ in the core 112, wherein the mounting of the die 200 may include mounting the die 200 in the core opening O₁₁₂, the package substrate 110 may include a power supply path P in a direction from the bottom side of the core 112 to the top side of the core 112, and the TSV 203 may be in the power supply path P of the package substrate 110. In one embodiment, the die 200 may include a plurality of dies in a die stack 400, the plurality of dies may be bonded together by a hybrid bond HB and the TSVs 203 in the plurality of dies may be substantially aligned in the power supply path P of the package substrate 110.

Referring again to FIGS. 1A-15, a package structure may include a package substrate 110, including a core 112 including a core opening O₁₁₂, a dielectric filling layer 115 in the core opening O₁₁₂, a die 200 in the dielectric filling layer 115 and including a through silicon via (TSV) 203 extending from a first side 200s1 of the die 200 to a second side 200s2 of the die 200 opposite the first side 200s1, an upper build-up portion 114 on a top side of the core 112 and electrically coupled to the TSV 203 in the die 200, a lower build-up portion 116 on a bottom side of the core 112 and electrically coupled to the TSV 203 in the die 200, and a ball grid array (BGA) 180 on a bottom side of the lower build-up portion 116, and a top die 140 mounted on the package substrate 110 and electrically coupled to the BGA 180 through the upper build-up portion 114 of the package substrate 110, the TSV 203 in the die 200 and the lower build-up portion 116 of the package substrate 110.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package substrate, comprising:
a core;
a dielectric filling layer formed at least on the core or in the core; and
a die in the dielectric filling layer, comprising:
a device region on a first side of the die; and
a through silicon via (TSV) extending from the first side of the die,
through the device region, and to a second side of the die opposite the first side of the die.

2. The package substrate of claim 1, wherein the package substrate comprises a power supply path in a direction from a bottom side of the core to a top side of the core, and the TSV is in the power supply path of the package substrate.

3. The package substrate of claim 1, wherein the core comprises a core opening, the dielectric filling layer is in the core opening and the die is in the core opening.

4. The package substrate of claim 3, wherein the core opening is defined by an inner sidewall of the core, and the die is separated from the inner sidewall of the core by a keep-out zone.

5. The package substrate of claim 3, wherein the core opening extends through an entirety of the core and the dielectric filling layer comprises:
a dielectric filling layer upper portion on a top side of the core; and
a dielectric filling layer lower portion on a bottom side of the core.

6. The package substrate of claim 5, further comprising:
an upper build-up portion including a metal interconnect structure on the dielectric filling layer upper portion; and
a lower build-up portion including a metal interconnect structure on the dielectric filling layer lower portion, wherein the TSV is electrically coupled to the metal interconnect structure in the upper build-up portion and to the metal interconnect structure in the lower build-up portion.

7. The package substrate of claim 6, wherein the die comprises a plurality of dies in a die stack, and the plurality of dies are bonded together by a hybrid bond.

8. The package substrate of claim 7, wherein the die stack comprises:
an upper die bonding pad electrically coupled to the metal interconnect structure in the upper build-up portion; and
a lower die bonding pad electrically coupled to the metal interconnect structure in the lower build-up portion, wherein the TSVs in the plurality of dies are substantially aligned and electrically couple the upper die bonding pad to the lower die bonding pad.

9. The package substrate of claim 1, wherein the core comprises a plurality of cores in a core stack, the plurality of cores includes a lower core and an upper core including a first opening stacked on the lower core, and the die comprises a first die in the first opening.

10. The package substrate of claim 9, wherein a thickness of the upper core is substantially the same as a thickness of the lower core.

11. The package substrate of claim 9, wherein a thickness of the upper core is less than a thickness of the lower core.

12. The package substrate of claim 9, wherein the upper core is separated from the lower core by a metal core separating layer, and the first die is mounted on the metal core separating layer.

13. The package substrate of claim 12, wherein the lower core comprises a second opening, and the die comprises a second die in the second opening and mounted on the metal core separating layer.

14. The package substrate of claim 1, further comprising:
an upper prepreg layer on a top side of the core, wherein the dielectric filling layer comprises a first dielectric filling layer on the upper prepreg layer and the die comprises a first die in the first dielectric filling layer; and
a lower prepreg layer on a bottom side of the core, wherein the dielectric filling layer comprises a second dielectric filling layer on the lower prepreg layer and the die comprises a second die in the second dielectric filling layer.

15. The package substrate of claim 14, wherein the first die comprises a plurality of dies in a first die stack and bonded together by a hybrid bond, and the second die comprises a plurality of dies in a second die stack and bonded together by a hybrid bond.

16. The package substrate of claim 14, wherein the core comprises a core opening, the dielectric filling layer comprises a third dielectric filling layer in the core opening and between the upper prepreg layer and the lower prepreg layer, and the die comprises a third die in the core opening.

17. A method of making a package substrate, the method comprising:
providing a core;
mounting a die on the core or in the core, wherein the die comprises:
a device region on a first side of the die; and
a through silicon via (TSV) extending from the first side of the die,
through the device region, and to a second side of the die opposite the first side of the die; and
forming a dielectric filling layer around the die.

18. The method of claim 17, further comprising:
forming a core opening in the core, wherein the mounting of the die comprises mounting the die in the core opening, the package substrate comprises a power supply path in a direction from the bottom side of the core to the top side of the core, and the TSV is in the power supply path of the package substrate.

19. The method of claim 18, wherein the die comprises a plurality of dies in a die stack, the plurality of dies are bonded together by a hybrid bond and the TSVs in the plurality of dies are substantially aligned in the power supply path of the package substrate.

20. A package structure, comprising:
a package substrate, comprising:
a core including a core opening;
a dielectric filling layer in the core opening;
a die in the dielectric filling layer and including a through silicon via (TSV) extending from a first side of the die to a second side of the die opposite the first side;
an upper build-up portion on a top side of the core and electrically coupled to the TSV in the die;
a lower build-up portion on a bottom side of the core and electrically coupled to the TSV in the die; and
a ball grid array (BGA) on a bottom side of the lower build-up portion; and
a top die mounted on the package substrate and electrically coupled to the BGA through the upper build-up portion of the package substrate, the TSV in the die and the lower build-up portion of the package substrate.
